(19) United States
(12) Patent Application Publication
(10) Pub. No.: US 2024/0339330 A1
(43) Pub. Date: Oct. 10, 2024

(54) METHOD FOR MANUFACTURING SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Makoto SHIMOSAWA, Matsumoto-city (JP); Takashi YOSHIMURA, Matsumoto-city (JP)

(21) Appl. No.: 18/749,528

(22) Filed: Jun. 20, 2024

Related U.S. Application Data
(63) Continuation of application No. PCT/JP2023/025208, filed on Jul. 6, 2023.

(30) Foreign Application Priority Data
Jul. 11, 2022 (JP) 2022-111117

(51) Int. Cl. H01L 21/311; H01L 21/768; H01L 27/07; H01L 29/66; H01L 29/861

(52) U.S. Cl. CPC H01L 21/31116; H01L 21/31144; H01L 21/76877; H01L 21/76897; H01L 29/66348; H01L 27/0727; H01L 29/8611

(57) ABSTRACT

Provided is a method for manufacturing a semiconductor device, the method including: forming an interlayer dielectric film having a contact hole above the semiconductor substrate; forming an initial metal film containing a predetermined first metal on an upper surface of the semiconductor substrate and on side walls of the interlayer dielectric film; forming a first alloy layer containing the first metal on the upper surface of the semiconductor substrate; forming a first barrier metal portion containing the first metal on the side walls of the interlayer dielectric film; etching at least one of the initial metal film or the first barrier metal portion; forming an oxide layer on an upper surface of the first alloy layer; etching the oxide layer; forming a second barrier metal portion, which is conductive, above the first alloy layer; and forming a plug layer above the second barrier metal portion.

The contents of the following patent application(s) are incorporated herein by reference:
NO. 2022-111117 filed in JP on Jul. 11, 2022
NO. PCT/JP2023/025208 filed in WO on Jul. 6, 2023

### BACKGROUND

### 1. Technical Field

The present invention relates to a method for manufacturing a semiconductor device.

### 2. Related Art

Patent Document 1 describes a semiconductor device in which a “silicide layer” is provided in a “contact hole”.

### PRIOR ART DOCUMENT

### Patent Document

Patent Document 1: Japanese Patent Application Publication No. 2003-318396
Patent Document 2: Japanese Patent Application Publication No. 2007-335554
Patent Document 3: Japanese Patent Application Publication No. 2002-334850

### BRIEF DESCRIPTION OF THE DRAWINGS

FIG. 1A shows one example of a top view of a semiconductor device 100.

FIG. 1B shows one example of a cross section a-a′ in FIG. 1A.

FIG. 2A shows a top view of a modified example of a semiconductor device 100.

FIG. 2B shows a top view of the modified example of the semiconductor device 100.

FIG. 2C shows a cross section b-b′ of the modified example of the semiconductor device 100.

FIG. 3A is an enlarged view of a cross section of a semiconductor device 100.

FIG. 3B is an enlarged view of a cross section of a semiconductor device 100.

FIG. 4A is an enlarged view of a cross section of a semiconductor device 100 as a modified example.

FIG. 4B is an enlarged view of a cross section of a semiconductor device 100 as a modified example.

FIG. 5A is an enlarged view of a cross section of a semiconductor device 100 as a modified example.

FIG. 5B is an enlarged view of a cross section of a semiconductor device 100 as a modified example.

FIG. 6A is an enlarged view of a cross section of a semiconductor device 100 as a modified example.

FIG. 6B is an enlarged view of a cross section of a semiconductor device 100 as a modified example.

FIG. 7A is an enlarged view of a cross section of a semiconductor device 100 as a modified example.

FIG. 7B is an enlarged view of a cross section of a semiconductor device 100 as a modified example.

FIG. 8A is an enlarged view of a cross section of a semiconductor device 100 as a modified example.

FIG. 8B is an enlarged view of a cross section of a semiconductor device 100 as a modified example.

FIG. 9A shows one example of a cross section c-c′ in FIG. 1A or FIG. 2B.

FIG. 9B shows one example of a cross section d-d′ in FIG. 1A or FIG. 2B.

FIG. 10A shows one example of a top view of a semiconductor device 100 including a temperature sensing unit 180.

FIG. 10B is one example of an enlarged view of a cross section in the temperature sensing unit 180.

FIG. 11 is a flowchart showing one example of a process of manufacturing a semiconductor device 100.

FIG. 12A shows one example of a process of forming an oxide layer 66.

FIG. 12B shows one example of a process of forming an oxide layer 66.

FIG. 12C shows one example of a process of forming an oxide layer 66.

FIG. 12D shows one example of a process of forming an oxide layer 66.

FIG. 13 shows one example of a method for manufacturing a semiconductor device 100.

FIG. 14 is a flowchart showing a process of manufacturing a semiconductor device according to a comparative example.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z axis direction and the −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X axis direction and the Y axis direction.

In the present specification, a description of a P+ type or an N+ type means a higher doping concentration than that of a P type or an N type, and a description of a P− type or an N− type means a lower doping concentration than that of the P type or the N type.

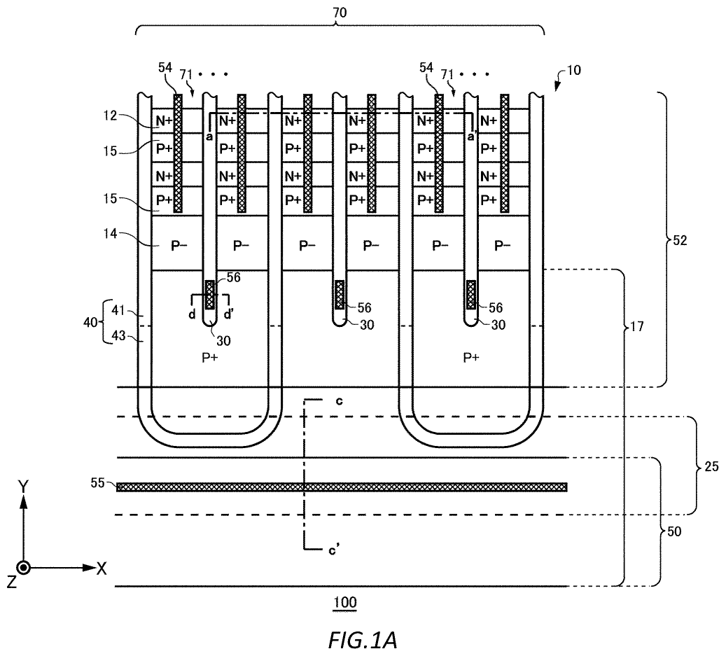

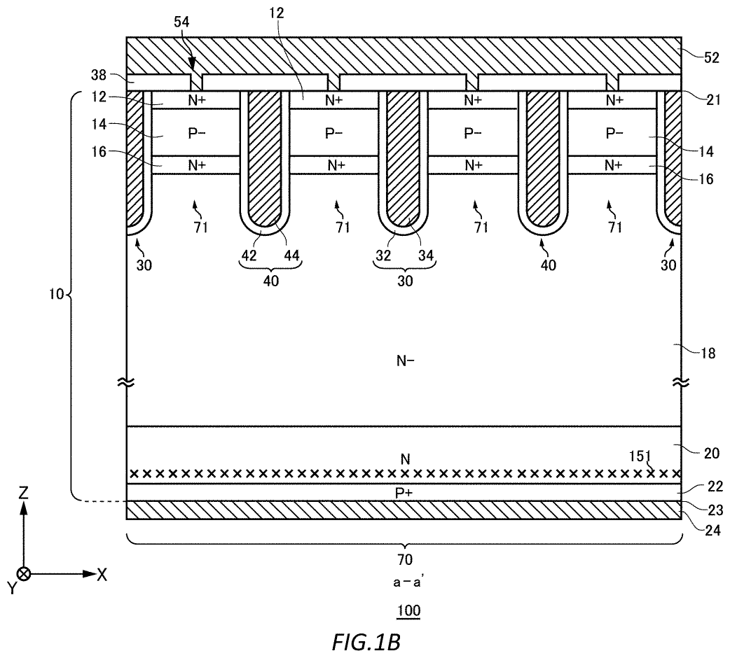

FIG. 1A shows one example of a top view of a semiconductor device 100. The semiconductor device 100 in the present example is a semiconductor chip including a transistor portion 70. The semiconductor device 100 is not limited to a transistor as long as it is a semiconductor element in which a semiconductor substrate 10 has a MOS gate structure.

The transistor portion 70 is a region obtained by projecting a collector region 22 provided on a back surface side of the semiconductor substrate 10 onto the upper surface of the semiconductor substrate 10. The collector region 22 will be described later. The transistor portion 70 includes a transistor such as an IGBT. In the present example, the transistor portion 70 is the IGBT. It is to be noted that the transistor portion 70 may be another transistor such as a MOSFET.

In the present figure, a region around an active portion of the semiconductor device 100 is shown, and illustration of another region is omitted. For example, an edge termination structure portion may be provided in a region on a negative side in the Y axis direction in the semiconductor device 100 in the present example. The edge termination structure portion reduces electric field strength on an upper surface side of the semiconductor substrate 10. The edge termination structure portion has, for example, a guard ring, a field plate, a RESURF, and a structure combining these. It is to be noted that although the present example describes an edge on the negative side in the Y axis direction for convenience, the same applies to other edges of the semiconductor device 100.

The semiconductor substrate 10 is a substrate that is formed of a semiconductor material. The semiconductor substrate 10 may be a silicon substrate, may be a silicon carbide substrate, may be a gallium nitride substrate, may be a diamond substrate, or may be another substrate. The semiconductor substrate 10 in the present example is the silicon substrate. It is to be noted that, when simply referred to as a top view in the present specification, it means that the semiconductor substrate 10 is viewed from the upper surface side. As will be described later, the semiconductor substrate 10 includes a front surface 21 and a back surface 23.

The semiconductor device 100 in the present example includes, at the front surface 21 of the semiconductor substrate 10, a gate trench portion 40, a dummy trench portion 30, an emitter region 12, a base region 14, a contact region 15, and a well region 17. In addition, the semiconductor device 100 in the present example includes an emitter electrode 52 and a gate metal layer 50 which are provided above the front surface 21 of the semiconductor substrate 10. The emitter electrode 52 and the gate metal layer 50 are one example of a front surface side metal layer 53 to be described later. The gate trench portion 40 is one example of the MOS gate structure provided in the semiconductor device 100. It is to be noted that although the semiconductor device 100 in the present example is a transistor including the MOS gate structure, the semiconductor device 100 may alternatively be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above a connection portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or of a metal alloy such as an aluminum-silicon alloy (AlSi) or an aluminum-silicon-copper alloy (AlSiCu). The emitter electrode 52 and the gate metal layer 50 may include a barrier metal layer formed of titanium, a titanium compound, or the like under the region formed of aluminum and the like. The barrier metal layer will be described later. The emitter electrode 52 and the gate metal layer 50 are provided separately from each other.

The emitter electrode 52 and the gate metal layer 50 are provided with an interlayer dielectric film 38 sandwiched therebetween, above the semiconductor substrate 10. The interlayer dielectric film 38 is omitted in FIG. 1A. A contact hole 54, a contact hole 55, and a contact hole 56 are provided through the interlayer dielectric film 38.

The contact hole 55 electrically connects the gate metal layer 50 and a gate conductive portion in the transistor portion 70 via the connection portion 25. A plug layer formed of tungsten or the like may be formed inside the contact hole 55. The plug layer will be described later.

The contact hole 56 connects the emitter electrode 52 with a dummy conductive portion inside the dummy trench portion 30. A plug layer formed of tungsten or the like may be formed inside the contact hole 56.

The connection portion 25 is connected to the front surface side metal layer 53 such as the emitter electrode 52 or the gate metal layer 50. In one example, the connection portion 25 is provided between the gate metal layer 50 and the gate conductive portion. The connection portion 25 in the present example may be provided extending in the X axis direction and electrically connected to the gate conductive portion. The connection portion 25 may be provided between the emitter electrode 52 and the dummy conductive portion as well. In the present example, the connection portion 25 is not provided between the emitter electrode 52 and the dummy conductive portion. The connection portion 25 is formed of a conductive material such as polysilicon doped with an impurity. The connection portion 25 in the present example is polysilicon doped with an impurity of the N type (N+). The connection portion 25 is provided above the front surface 21 of the semiconductor substrate 10 via a dielectric film such as an oxide film, or the like.

Gate trench portions 40 are examples of a plurality of trench portions extending in a predetermined extending direction on a front surface 21 side of the semiconductor substrate 10. The gate trench portions 40 are arrayed at a predetermined interval along a predetermined array direction (the X axis direction in the present example). The gate trench portion 40 in the present example may include two extending portions 41 which extend along an extending direction (the Y axis direction in the present example) parallel to the front surface 21 of the semiconductor substrate 10 and perpendicular to the array direction, and a connecting portion 43 which connects the two extending portions 41.

At least part of the connecting portion 43 is preferably formed in a curved shape. Connecting end portions of the two extending portions 41 of the gate trench portion 40 can reduce electric field strength at the end portions of the extending portions 41. At the connecting portion 43 of the gate trench portion 40, the gate metal layer 50 may be electrically connected to the gate conductive portion via the connection portion 25.

Dummy trench portions 30 are examples of a plurality of trench portions extending in a predetermined extending direction on the front surface 21 side of the semiconductor substrate 10. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). The dummy trench portion 30 in the present example has an I shape at the front surface 21 of the semiconductor substrate 10, but may have a U shape at the front surface 21 of the semiconductor substrate 10 similarly to the gate trench portion 40. That is, the dummy trench portion 30 may include two extending portions which extend along the extending direction and a connecting portion which connects the two extending portions.

The transistor portion 70 in the present example has a structure in which two gate trench portions 40 and two dummy trench portions 30 are repetitively arrayed. That is, the transistor portion 70 in the present example includes the gate trench portions 40 and the dummy trench portions 30 at a ratio of 1:1. For example, the transistor portion 70 includes one dummy trench portion 30 between two extending portions 41.

It should be noted that the ratio between the gate trench portions 40 and the dummy trench portions 30 is not limited to that in the present example. The ratio of the gate trench portions 40 may be greater than the ratio of the dummy trench portions 30, or the ratio of the dummy trench portions 30 may be greater than the ratio of the gate trench portions 40. The ratio between the gate trench portions 40 and the dummy trench portions 30 may be 2:3, or may be 2:4. In addition, the transistor portion 70 may not include the dummy trench portions 30 with all trench portions being the gate trench portions 40.

The well region 17 is a region of a second conductivity type which is provided on the front surface 21 side of the semiconductor substrate 10 relative to a drift region 18 to be described later. The well region 17 is one example of a well region provided on a peripheral side of an active portion 120. The well region 17 is of the P+ type as one example. The well region 17 is formed in a predetermined range from an end portion of an active region on a side where the gate metal layer 50 is provided. A diffusion depth of the well region 17 may be greater than depths of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

The contact hole 54 is formed above each of the emitter region 12 and the contact region 15 in the transistor portion 70. The contact hole 54 is not provided above well regions 17 provided at both ends in the Y axis direction. In this manner, one or more contact holes 54 are formed in the interlayer dielectric film. The one or more contact holes 54 may be provided extending in the extending direction.

A mesa portion 71 is a mesa portion provided in direct contact with the trench portion in a plane parallel to the front surface 21 of the semiconductor substrate 10. The mesa portion may be a portion of the semiconductor substrate 10 sandwiched between two adjacent trench portions, and may be a portion from the front surface 21 of the semiconductor substrate 10 to a depth of the lowermost bottom portion of each trench portion. An extending portion of each trench portion may be defined as one trench portion. That is, the region sandwiched between two extending portions may be defined as a mesa portion.

The mesa portion 71 is provided in direct contact with at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, emitter regions 12 and contact regions 15 are alternately provided in the extending direction.

The base region 14 is a region of the second conductivity type which is provided on the front surface 21 side of the semiconductor substrate 10. The base region 14 is of the P− type as one example. The base regions 14 may be provided at both end portions of the mesa portion 71 in the Y axis direction at the front surface 21 of the semiconductor substrate 10. It is to be noted that FIG. 1A shows only one end portion in the Y axis direction of the base region 14.

The emitter region 12 is a region of a first conductivity type having a higher doping concentration than the drift region 18. The emitter region 12 in the present example is of the N+ type as one example. Examples of a dopant of the emitter region 12 include arsenic (As). The emitter region 12 is provided in contact with the gate trench portion 40 at the front surface 21 in the mesa portion 71. The emitter region 12 may be provided extending in the X axis direction from one to another of two trench portions sandwiching the mesa portion 71. The emitter region 12 is also provided below the contact hole 54.

In addition, the emitter region 12 may be or may not be in contact with the dummy trench portion 30. The emitter region 12 in the present example is in contact with the dummy trench portion 30.

The contact region 15 is a region of the second conductivity type provided above the base region 14 and having a higher doping concentration than the base region 14. The contact region 15 in the present example is of the P+ type as one example. The contact region 15 in the present example is provided at the front surface 21 in the mesa portion 71. The contact region 15 may be provided in the X axis direction from one to another of the two trench portions sandwiching the mesa portion 71. The contact region 15 may be or may not be in contact with the gate trench portion 40 or the dummy trench portion 30. The contact region 15 in the present example is in contact with the dummy trench portion 30 and the gate trench portion 40. The contact region 15 is also provided below the contact hole 54.

FIG. 1B shows one example of a cross section a-a′ in FIG. 1A. The cross section a-a′ is the XZ plane which passes through the emitter region 12 in the transistor portion 70. The semiconductor device 100 in the present example includes the semiconductor substrate 10, the interlayer dielectric film 38, the emitter electrode 52, and a collector electrode 24 in the cross section a-a′. The collector electrode 24 is one example of a back surface side metal layer provided in contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as one example. The drift region 18 may be a region which has remained without other doping regions formed in the semiconductor substrate 10. That is, a doping concentration in the drift region 18 may be a doping concentration in the semiconductor substrate 10.

A buffer region 20 is a region of the first conductivity type which is provided on a back surface 23 side of the semiconductor substrate 10 relative to the drift region 18. The buffer region 20 in the present example is of the N type as one example. The doping concentration of the buffer region 20 is higher than the doping concentration of the drift region 18. The buffer region 20 may function as a field stop layer which prevents a depletion layer expanding from a lower surface side of the base region 14 from reaching the collector region 22 of the second conductivity type. It is to be noted that the buffer region 20 may be omitted.

The collector region 22 is provided below the buffer region 20 in the transistor portion 70. The collector region 22 has the second conductivity type. The collector region 22 in the present example is of the P+ type as one example.

The collector electrode 24 is formed at the back surface 23 of the semiconductor substrate 10. The collector electrode 24 is formed of a conductive material such as metal. A material of the collector electrode 24 may be the same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may be or may not be in contact with the dummy trench portion 30.

An accumulation region 16 is a region of the first conductivity type which is provided on the front surface 21 side of the semiconductor substrate 10 relative to the drift region 18. The accumulation region 16 in the present example is of the N+ type as one example. It should be noted that the accumulation region 16 may not be provided.

The accumulation region 16 is provided in contact with the gate trench portion 40. The accumulation region 16 may be or may not be in contact with the dummy trench portion 30. A doping concentration in the accumulation region 16 is higher than the doping concentration in the drift region 18. An ion implantation dose amount in the accumulation region 16 may be 1.0E+12 cm⁻² or more and 1.0E+13 cm⁻² or less. In addition, the ion implantation dose amount in the accumulation region 16 may be 3.0E+12 cm⁻² or more and 6.0E+12 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, or the accumulation region 16, each trench portion also passes through these regions to reach the drift region 18. The configuration of the trench portion penetrating the doping region is not limited to the one manufactured in the order of forming the doping region and then forming the trench portion. The configuration of the trench portion passing through the doping region includes a configuration of the doping region being formed between the trench portions after forming the trench portion.

The gate trench portion 40 includes a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on the side of the mesa portion 71 by sandwiching the gate dielectric film 42 in a depth direction of the semiconductor substrate 10. When a predetermined voltage is applied to the gate conductive portion 44, a channel is formed by an electron inversion layer in a surface layer of the base region 14 at a boundary in contact with the gate trench.

The dummy trench portion 30 may have the same structure as that of the gate trench portion 40. The dummy trench portion 30 includes a dummy trench, a dummy dielectric film 32, and a dummy conductive portion 34 which are formed on the front surface 21 side. The dummy dielectric film 32 is formed covering the inner walls of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may be provided to pass through the interlayer dielectric film 38. A film thickness of the interlayer dielectric film 38 is, for example, 1.0 μm, but it is not limited to this.

The interlayer dielectric film 38 may be a silicon oxide film. The interlayer dielectric film 38 may be a boro-phospho silicate glass (BPSG) film, may be a borosilicate glass (BSG) film, or may be a phosphosilicate glass (PSG) film. The interlayer dielectric film 38 may also include a high temperature silicon oxide (HTO: High Temperature Oxide) film.

A back surface side lifetime control region 151 may be provided in the transistor portion 70. It should be noted that the back surface side lifetime control region 151 may be omitted. The back surface side lifetime control region 151 is a region where a lifetime killer has intentionally been formed by implanting an impurity inside the semiconductor substrate 10, or the like. As one example, the back surface side lifetime control region 151 is formed by implanting helium into the semiconductor substrate 10. The back surface side lifetime control region 151 may also be formed by implanting protons. By providing the back surface side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. In addition, the lifetime killer may be a noble gas element such as helium or neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a concentration of a defect complex of these vacancies with elements constituting the semiconductor substrate 10, or may be a dislocation concentration. In addition, the lifetime killer concentration may be a chemical concentration of a noble gas element such as helium or neon, or may be a chemical concentration of a metal element such as platinum.

The back surface side lifetime control region 151 is provided on the back surface 23 side with respect to the center of the semiconductor substrate 10 in the depth direction of the semiconductor substrate 10. The back surface side lifetime control region 151 in the present example is provided in the buffer region 20. The back surface side lifetime control region 151 in the present example is provided on an entire surface of the semiconductor substrate 10 in the XY plane, and can be formed without using a mask. The back surface side lifetime control region 151 may be provided in a part of the semiconductor substrate 10 in the XY plane. An impurity dose amount for forming the back surface side lifetime control region 151 may be 0.5 E+10 cm⁻² or more and 1.0 E+14 cm⁻² or less, or may be 5.0 E+10 cm⁻² or more and 1.0 E+13 cm⁻² or less.

The back surface side lifetime control region 151 may be formed by an implantation from the back surface 23 side. Accordingly, it becomes easy to avoid an influence on the front surface 21 side of the semiconductor device 100. For example, the back surface side lifetime control region 151 is formed by irradiating helium or a proton from the back surface 23 side. Herein, which of the front surface 21 side and the back surface 23 side the implantation is performed from for forming the back surface side lifetime control region 151 can be determined by acquiring a state of the front surface 21 side by an SRP method or a measurement of a leakage current.

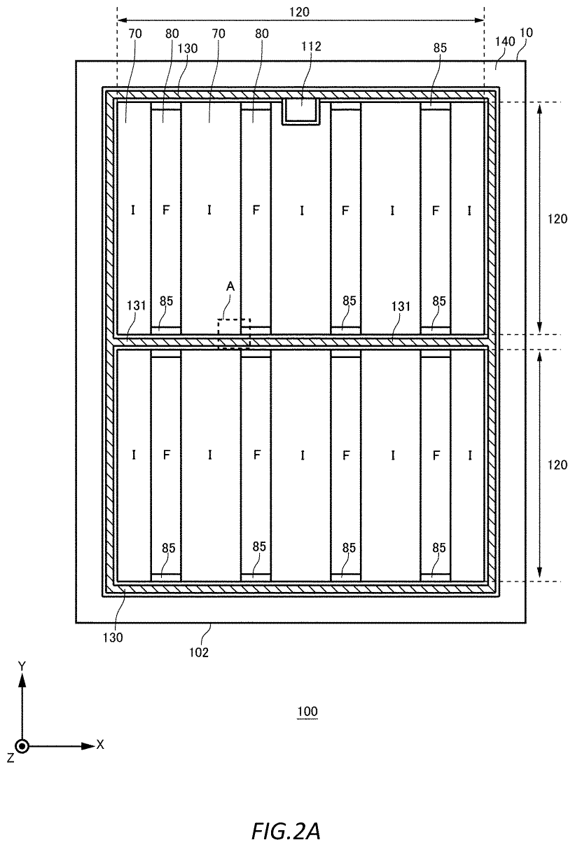

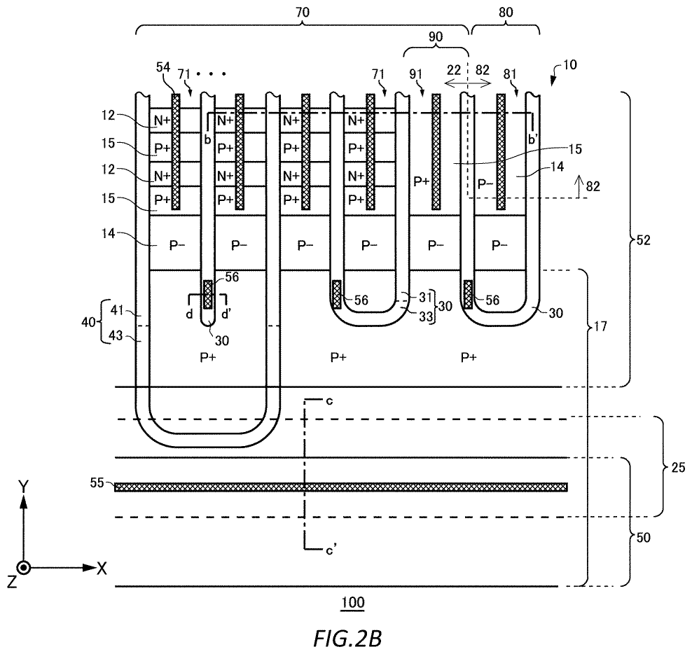

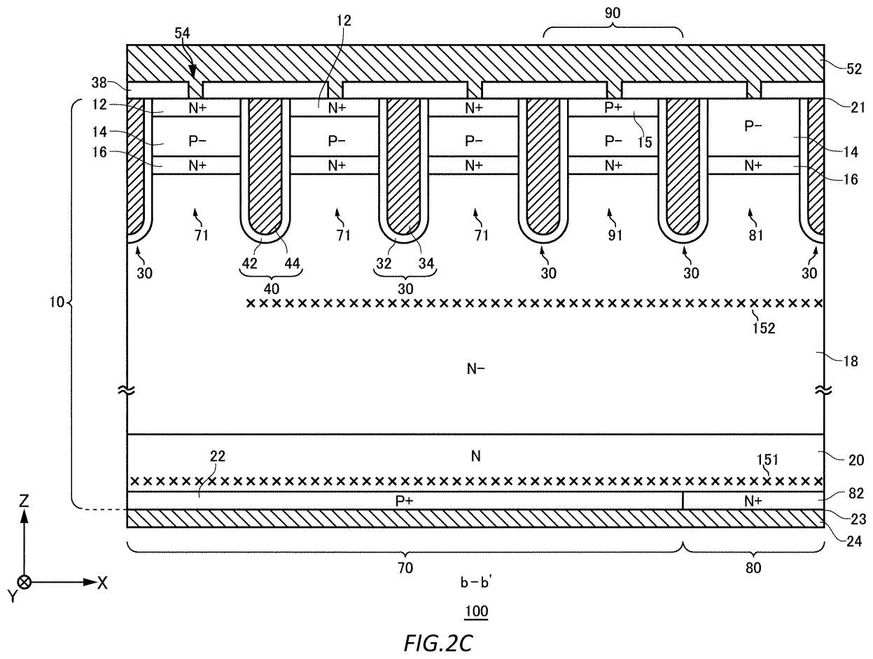

FIG. 2A shows a top view of a modified example of a semiconductor device 100. In the present example, only some members of the semiconductor device 100 are shown, and illustration of some members is omitted.

A semiconductor substrate 10 includes an end side 102 in a top view. The semiconductor substrate 10 in the present example includes two sets of end sides 102 facing each other in a top view. In the present example, the X axis and the Y axis are parallel to any of the end sides 102.

The semiconductor substrate 10 is provided with an active portion 120. The active portion 120 is a region where a main current flows in the depth direction between a front surface 21 and a back surface 23 of the semiconductor substrate 10 when the semiconductor device 100 operates. An emitter electrode 52 is provided above the active portion 120, but illustration thereof is omitted in the present figure.

The active portion 120 is provided with at least one of a transistor portion 70 including a transistor element such as an IGBT or a diode portion 80 including a diode element such as a freewheeling diode (FWD). In the example of FIG. 2A, the transistor portion 70 and the diode portion 80 are alternately arranged along a predetermined array direction (the X axis direction in the present example) at the front surface 21 of the semiconductor substrate 10. In another example, the active portion 120 may be provided with only one of the transistor portion 70 and the diode portion 80.

In the present example, a region where the transistor portion 70 is arranged is denoted by a symbol “I”, and a region where the diode portion 80 is arranged is denoted by a symbol “F”. The transistor portion 70 and the diode portion 80 may each have a longitudinal length in an extending direction. In other words, a length of the transistor portion 70 in the Y axis direction is larger than a width in the X axis direction. Similarly, a length of the diode portion 80 in the Y axis direction is larger than a width in the X axis direction. The extending direction of the transistor portion 70 and the diode portion 80, and a longitudinal direction of each trench portion to be described later may be the same.

The diode portion 80 is a region obtained by projecting a cathode region 82 provided on a back surface 23 side of the semiconductor substrate 10 onto an upper surface of the semiconductor substrate 10. The cathode region 82 will be described later. At the back surface 23 of the semiconductor substrate 10, a collector region 22 of the P+ type may be provided in a region other than the cathode region 82. In the present specification, the diode portion 80 may also include an extension region 85 where the diode portion 80 extends in the Y axis direction to a gate runner to be described later. At the back surface 23 of the extension region 85, the collector region 22 may be provided.

The semiconductor device 100 may include one or more pads above the semiconductor substrate 10. The semiconductor device 100 in the present example includes a gate pad 112. The semiconductor device 100 may include pads such as an anode pad and a cathode pad. Each pad is arranged in the vicinity of the end side 102. The vicinity of the end side 102 refers to a region between the end side 102 and the emitter electrode 52 in a top view. When the semiconductor device 100 is mounted, each pad may be connected to an external circuit via a wiring line such as a wire.

A gate potential is applied to the gate pad 112. The gate pad 112 is electrically connected to a gate conductive portion 44 of a gate trench portion 40 in the active portion 120. The semiconductor device 100 includes the gate runner which connects the gate pad 112 and the gate trench portion 40. In FIG. 2A, the gate runner is hatched with diagonal lines.

The gate runner in the present example includes an outer circumferential gate runner 130 and a gate runner between active portions 131. The gate runner may be composed of either a gate metal layer 50 or a connection portion 25, or a combination of both as appropriate. The outer circumferential gate runner 130 and the gate runner between active portions 131 may have the same configuration, or may have different configurations. The outer circumferential gate runner 130 is arranged between the active portion 120 and the end side 102 of the semiconductor substrate 10 in a top view. The outer circumferential gate runner 130 in the present example encloses the active portion 120 in a top view. A region enclosed by the outer circumferential gate runner 130 in a top view may be the active portion 120. In addition, the outer circumferential gate runner 130 is connected to the gate pad 112. The outer circumferential gate runner 130 is arranged above the semiconductor substrate 10. The outer circumferential gate runner 130 may be composed of the gate metal layer 50 and the connection portion 25.

The gate runner between active portions 131 is provided between a plurality of active portions 120. In FIG. 2A, two active portions 120 are arranged side by side in the Y axis direction. Providing the gate runner between active portions 131 between the plurality of active portions 120 inside the semiconductor substrate 10 can reduce a variation in wiring length from the gate pad 112 for each region of the semiconductor substrate 10.

The gate runner between active portions 131 is connected to the gate trench portion of the active portion 120. The gate runner between active portions 131 is arranged above the semiconductor substrate 10. The gate runner between active portions 131 in the present example is composed of the gate metal layer 50 and the connection portion 25. The gate metal layer 50 may be a metal layer containing aluminum or the like.

The gate runner between active portions 131 may be connected to the outer circumferential gate runner 130. The gate runner between active portions 131 in the present example is provided extending in the X axis direction so as to cross the active portion 120 from one outer circumferential gate runner 130 to another outer circumferential gate runner 130 substantially at a center in the Y axis direction. When the active portion 120 is divided by the gate runner between active portions 131, the transistor portion 70 and the diode portion 80 may be alternately arranged in the X axis direction in each divided region.

An edge termination structure portion 140 is provided at the front surface 21 of the semiconductor substrate 10. The edge termination structure portion 140 is provided between the active portion 120 and the end side 102 in a top view. The edge termination structure portion 140 in the present example is arranged between the outer circumferential gate runner 130 and the end side 102. The edge termination structure portion 140 reduces electric field strength on a front surface 21 side of the semiconductor substrate 10. The edge termination structure portion 140 may include at least one of a guard ring, a field plate, or a RESURF which is annularly provided to enclose the active portion 120.

FIG. 2B shows a top view of the modified example of the semiconductor device 100. The semiconductor device 100 in the present example includes the transistor portion 70 and the diode portion 80. The present figure is an enlarged view of an upper surface of a region A in FIG. 2A.

The semiconductor device 100 in the present example includes the gate trench portion 40, a dummy trench portion 30, an emitter region 12, a base region 14, a contact region 15, and a well region 17 which are provided inside on the front surface 21 side of the semiconductor substrate 10. The gate trench portion 40 and the dummy trench portion 30 are each one example of a trench portion.

Similarly to the gate trench portion 40, the dummy trench portion 30 in the present example may have a U shape at the front surface 21 of the semiconductor substrate 10. That is, the dummy trench portion 30 may include two extending portions 31 which extend along the extending direction and a connecting portion 33 which connects two extending portions 31.

The semiconductor device 100 in the present example includes the emitter electrode 52 and the gate metal layer 50 which are provided above the front surface 21 of the semiconductor substrate 10. The emitter electrode 52 and the gate metal layer 50 are provided separately from each other. The transistor portion 70 in the present example includes a boundary portion 90 that is positioned at a boundary between the transistor portion 70 and the diode portion 80. It should be noted that the semiconductor device 100 may not include the boundary portion 90.

The boundary portion 90 is a region which is provided in the transistor portion 70 and is in direct contact with the diode portion 80. The boundary portion 90 includes the contact region 15 at the front surface 21 of the semiconductor substrate 10. The boundary portion 90 in the present example does not include the emitter region 12. In one example, trench portions in the boundary portion 90 are dummy trench portions 30. The boundary portion 90 in the present example is arranged such that both ends thereof in the X axis direction become the dummy trench portions 30.

A contact hole 54 is provided above the base region 14 in the diode portion 80. The contact hole 54 is provided above the contact region 15 in the boundary portion 90. No contact holes 54 are provided above the well regions 17 provided at both ends in the Y axis direction.

A mesa portion 91 is provided in the boundary portion 90. The mesa portion 91 includes the contact region 15 at the front surface 21 of the semiconductor substrate 10. The mesa portion 91 in the present example includes the base region 14 and the well region 17 on a negative side in the Y axis direction.

A mesa portion 81 is provided in a region sandwiched between the dummy trench portions 30 adjacent to each other in the diode portion 80. The mesa portion 81 includes the base region 14 at the front surface 21 of the semiconductor substrate 10. The mesa portion 81 in the present example includes the well region 17 on a negative side in the Y axis direction.

The emitter region 12 is provided in a mesa portion 71, but may not be provided in the mesa portion 81 and the mesa portion 91. The contact region 15 is provided in the mesa portion 71 and the mesa portion 91, but may not be provided in the mesa portion 81.

FIG. 2C shows a cross section b-b′ of the modified example of the semiconductor device 100. The present figure corresponds to the cross section b-b′ in FIG. 2B. The semiconductor device 100 in the present example includes a back surface side lifetime control region 151 and a front surface side lifetime control region 152. It should be noted that the semiconductor device 100 may not include one of the back surface side lifetime control region 151 or the front surface side lifetime control region 152. The semiconductor device 100 in the present example includes the collector region 22 and the cathode region 82 on the back surface 23 side of a buffer region 20.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

An accumulation region 16 is provided in the transistor portion 70 and the diode portion 80. The accumulation region 16 in the present example is provided at entire surfaces of the transistor portion 70 and the diode portion 80. It should be noted that the accumulation region 16 may not be provided in the diode portion 80.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the boundary portion 90 in the present example.

The back surface side lifetime control region 151 is provided in both of the transistor portion 70 and the diode portion 80. This allows the semiconductor device 100 in the present example to speed up recovery in the diode portion 80 and further improve a switching loss. The back surface side lifetime control region 151 may be formed by a method similar to that of the back surface side lifetime control region 151 in other embodiment examples.

The front surface side lifetime control region 152 is provided closer to the front surface 21 side with respect to the center of the semiconductor substrate 10 in the depth direction of the semiconductor substrate 10. The front surface side lifetime control region 152 in the present example is provided in a drift region 18. The front surface side lifetime control region 152 is provided in both of the transistor portion 70 and the diode portion 80. The front surface side lifetime control region 152 may be provided in the diode portion 80 and the boundary portion 90 and not be provided in a part of the transistor portion 70. The front surface side lifetime control region 152 can suppress implantation of holes from the transistor portion 70 and the diode portion 80, to reduce a reverse recovery loss.

The front surface side lifetime control region 152 may be formed with any of the methods for forming the back surface side lifetime control region 151. The element, the dose amount, and the like for forming the back surface side lifetime control region 151 may be the same as or different from those for forming the front surface side lifetime control region 152.

The front surface side lifetime control region 152 is provided extending from the diode portion 80 to the transistor portion 70. The front surface side lifetime control region 152 may be formed by an irradiation from the front surface 21 of the semiconductor substrate 10. The front surface side lifetime control region 152 may alternatively be formed by an irradiation from the back surface 23 side of the semiconductor substrate 10. The front surface side lifetime control region 152 in the present example is provided below the gate trench portion 40. Due to particle beams or the like for forming the front surface side lifetime control region 152 passing through a MOS gate structure of the semiconductor device 100, a defect may be generated at a boundary between the gate oxide film and the semiconductor substrate.

The semiconductor device 100 may be a power semiconductor device for controlling electrical power, and the like. The semiconductor device 100 in the present example may have a vertical semiconductor structure in which a back surface side metal layer is provided on the back surface 23 side of the semiconductor substrate 10. It should be noted that, the semiconductor device 100 may have horizontal semiconductor structure in which no metal layer is provided on the back surface 23 side.

It is to be noted that, in the present example, an RC-IGBT having a trench gate structure is described as an example of the semiconductor device 100. It should be noted that the semiconductor device 100 may be a semiconductor device having a planar gate structure, or may be other semiconductor devices such as a diode. The semiconductor device 100 may include a MOSFET of an N channel, or may include a MOSFET of a P channel.

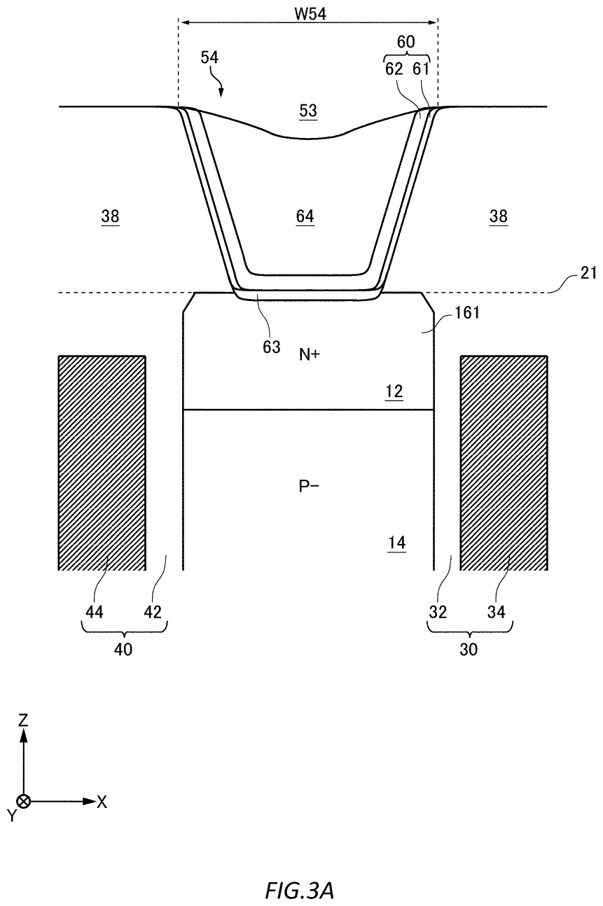

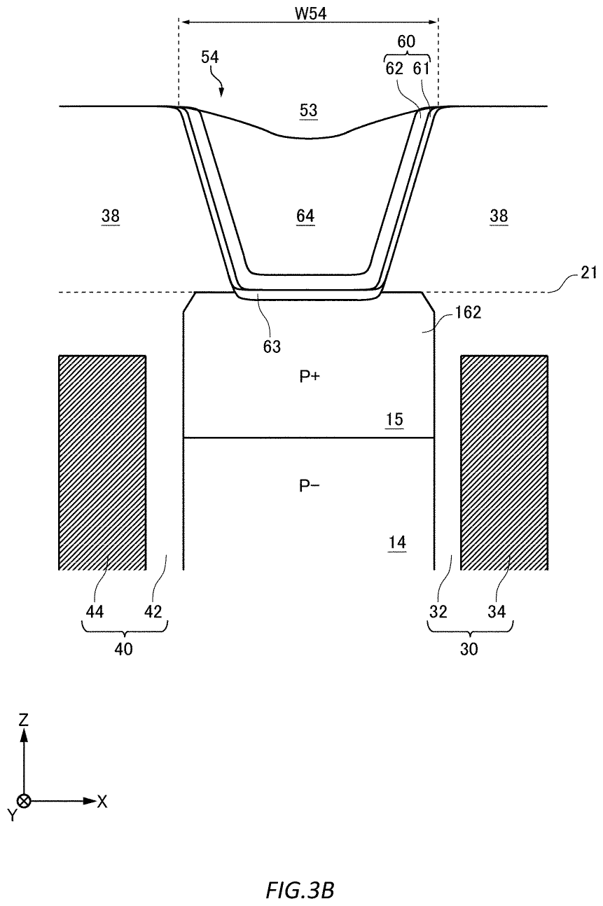

FIG. 3A is an enlarged view of a cross section of a semiconductor device 100. In the present example, the enlarged view of the cross section in the vicinity of a contact hole 54 is shown. The cross section in the present example is the XZ cross section which passes through the emitter region 12 at a front surface 21 of a semiconductor substrate 10. The emitter region 12 is one example of a first conductivity type region 161. The semiconductor device 100 includes a barrier metal layer 60, a first alloy layer 63, and a plug layer 64. The semiconductor device 100 in the present example does not include an oxide layer 66 to be described later.

It is to be noted that, in the present specification, the contact hole 54 may be used to describe the structure in the vicinity of the contact hole, but similar structures may also be applied to other contact holes such as a contact hole 55 and a contact hole 56. That is, the barrier metal layer 60, the first alloy layer 63, and the plug layer 64 may be provided in other contact holes such as the contact hole 55 and the contact hole 56. Similarly, the barrier metal layer 60, the first alloy layer 63, and the plug layer 64 may be provided for a contact hole 58 to be described later. As will be described later, when the oxide layer 66 is left in the contact hole 54, the oxide layer 66 may be provided in other contact holes such as the contact hole 55 and the contact hole 56.

The barrier metal layer 60 is provided above the first alloy layer 63 in the contact hole 54. The barrier metal layer 60 is provided on a bottom surface of the contact hole 54 and on side walls of an interlayer dielectric film 38. The barrier metal layer 60 may be provided in contact with an upper surface of the interlayer dielectric film 38. The barrier metal layer 60 in the present example is provided on an upper surface of the first alloy layer 63 and on the side walls of the interlayer dielectric film 38 in the contact hole 54. The barrier metal layer 60 contains a predetermined conductive first metal. The first metal may be at least one of titanium (Ti), cobalt (Co), nickel (Ni), tantalum (Ta), magnesium (Mg), vanadium (V), lanthanum (La), palladium (Pd), or zirconium (Zr). The first metal may be a metal having a hydrogen absorbing effect. The barrier metal layer 60 in the present example includes a first barrier metal portion 61 and a second barrier metal portion 62. It should be noted that the first barrier metal portion 61 may be removed in any of processes of manufacturing the semiconductor device 100.

The first barrier metal portion 61 is provided on the side walls of the interlayer dielectric film 38 in the contact hole 54. The first barrier metal portion 61 contains a predetermined conductive first metal. For example, the first barrier metal portion 61 is TIN. The first barrier metal portion 61 may be a hydrogen-absorbing metal. The first barrier metal portion 61 is formed by annealing an initial metal film 67 (not shown) containing the first metal. The first barrier metal portion 61 in the present example is TiN formed by annealing Ti, a film of which has been formed on the side walls of the interlayer dielectric film 38 as the initial metal film 67, in a nitrogen atmosphere.

The second barrier metal portion 62 is stacked on the first barrier metal portion 61 in the contact hole 54. The second barrier metal portion 62 contains a conductive material. For example, the second barrier metal portion 62 is TiN. The second barrier metal portion 62 is provided so as to be stacked on the first alloy layer 63 provided at an upper surface of the semiconductor substrate 10. The second barrier metal portion 62 may be formed by sputtering the conductive material. The second barrier metal portion 62 in the present example is TIN formed by sputtering. The second barrier metal portion 62 may be provided in contact with the first barrier metal portion 61 and the first alloy layer 63.

The first alloy layer 63 is provided on the upper surface of the semiconductor substrate 10 below the contact hole 54. The first alloy layer 63 in the present example is provided on the upper surface of the semiconductor substrate 10. The first alloy layer is formed by annealing the initial metal film 67 containing the first metal. The first alloy layer 63 may be an alloy consisting of the first metal and a constituent element of the layer at the bottom surface of the contact hole 54. As one example, when the semiconductor substrate 10 is a silicon substrate, the first alloy layer 63 may be a silicide layer. As another example, when the semiconductor substrate 10 is a silicon carbide substrate, a gallium nitride substrate, a diamond substrate, or the like, the first alloy layer 63 may be an alloy layer containing these substrate materials and the first metal. The first alloy layer 63 in the present example is a titanium silicide layer formed by annealing Ti, a film of which has been formed at the bottom surface of the contact hole 54 as the initial metal film 67. An N type region including the first conductivity type region 161 may be formed such that a concentration of an N type impurity is high at a place in contact with the first alloy layer 63, thereby reducing a contact resistance.

The first barrier metal portion 61 and the first alloy layer 63 may be formed in the same annealing process. For example, the first barrier metal portion 61 of TiN is formed on the side walls of the interlayer dielectric film 38, and the first alloy layer 63 of titanium silicide is formed at the upper surface of the semiconductor substrate 10. It is to be noted that all the initial metal film 67 which has been formed may be used for forming the first barrier metal portion 61 or the first alloy layer 63, and no initial metal film 67 may remain. The initial metal film 67 may remain on the first alloy layer 63, or the first barrier metal portion 61 may be formed on the first alloy layer 63 or the initial metal film 67.

The plug layer 64 is provided above the barrier metal layer 60 in the contact hole 54. The plug layer 64 may be provided in contact with the second barrier metal portion 62 in the contact hole 54. The plug layer 64 is a conductive material that is filled inside the contact hole 54. The material of the plug layer 64 may be different from that of a front surface side metal layer 53. For example, the material of the plug layer 64 is tungsten. It is to be noted that the plug layer 64 may be provided in contact with the second barrier metal portion 62 and above the interlayer dielectric film 38 also outside the contact hole 54. The plug layer 64 may be omitted, and the front surface side metal layer 53 may be filled inside the contact hole 54.

The interlayer dielectric film 38 includes the contact hole 54 and is provided above the semiconductor substrate 10. Although the interlayer dielectric film 38 includes one layer of a dielectric film provided above the front surface 21, the interlayer dielectric film 38 may alternatively include a plurality of stacked dielectric films. The interlayer dielectric film 38 may be a silicon oxide film such as BPSG.

The first barrier metal portion 61 is denser than the second barrier metal portion 62. The first barrier metal portion 61 and the second barrier metal portion 62 may be formed with different film formation methods. The first barrier metal portion 61 may be a TiN film formed by annealing Ti, a film of which has been formed on the side walls of the interlayer dielectric film 38. The second barrier metal portion 62 may be a TiN film formed by sputtering TiN. This may cause the first barrier metal portion 61 to be a TiN film denser than the second barrier metal portion 62. The first barrier metal portion 61 and the second barrier metal portion 62 may contain the same material.

Densely forming the first barrier metal portion 61 can protect the interlayer dielectric film 38 from damage caused during formation of the plug layer 64. On the other hand, since the second barrier metal portion 62 formed by sputtering does not need formation of the initial metal film 67, it is possible to avoid an influence of the hydrogen absorbing effect caused by remaining Ti or the like. It should be noted that, since the second barrier metal portion 62 is not a dense film like the first barrier metal portion 61, the plug layer 64 may enter the second barrier metal portion 62 during the formation of the plug layer 64.

A film thickness of the first barrier metal portion 61 may be smaller than a film thickness of the second barrier metal portion 62. The film thickness of the first barrier metal portion 61 may be smaller than a film thickness of the first alloy layer 63. The first barrier metal portion 61 may be thinned by etching performed after the dense film is formed. The etching performed after the dense film is formed may be performed using a chemical liquid. The chemical liquid used for performing the etching may be, for example, hydrofluoric acid, an ammonia hydrogen peroxide, sulfuric acid, or the like. The ammonia hydrogen peroxide is a mixed liquid of ammonia (NH₄OH), hydrogen peroxide (H₂O₂), and water (H₂O). The etching performed after the dense film is formed may be dry etching, reverse sputtering, or the like. The film thickness of the first barrier metal portion 61 may be 1 nm or more and 10 nm or less. The film thickness of the first barrier metal portion 61 may be a film thickness at a position where the first barrier metal portion 61 is the thickest in the contact hole 54. The film thickness of the first barrier metal portion 61 may be formed in a predetermined range on the entire side walls of the interlayer dielectric film 38. The film thickness of the second barrier metal portion 62 may be 1 nm or more and 100 nm or less. The film thickness of the first alloy layer 63 may be 1 nm or more and 200 nm or less.

The first barrier metal portion 61 may cover the side walls of the interlayer dielectric film 38. A lower end of the first barrier metal portion 61 may be in contact with the oxide layer 66. That is, the bottom surface of the contact hole 54 and the side walls of the interlayer dielectric film 38 may be covered with the first barrier metal portion 61 and the oxide layer 66. This can avoid erosion of the interlayer dielectric film 38 and the first alloy layer 63 by a gas generated during the formation of the plug layer 64. The oxide layer 66 may be formed on the upper surface of the first alloy layer 63 when it the first barrier metal portion 61 is thinned by etching.

An opening width W54 of the contact hole 54 is a width of the contact hole 54 in the trench array direction on the upper surface of the interlayer dielectric film 38. The opening width W54 of the contact hole 54 may be 100 nm or more and 1000 nm or less.

Herein, when electron beams, particle beams, and the like for forming a lifetime control region pass through a MOS gate structure, a defect may be generated in the vicinity of a boundary between the oxide film and the semiconductor layer in the MOS gate structure. Then, when metal such as Ti having a hydrogen absorbing effect exists in the vicinity of the MOS gate structure, hydrogen diffused in the gate portion may be absorbed so as to result in an inhibition of a hydrogen termination of a dangling bond of the MOS gate structure and a variation of a threshold voltage.

In the semiconductor device 100 in the present example, thinning the first barrier metal portion 61 can reduce a remaining amount of the first metal having the hydrogen absorbing effect. This can suppress the influence of the hydrogen absorbing effect and promote hydrogen termination of a dangling bond in the MOS gate structure. Accordingly, a variation in a threshold voltage can be suppressed.

When the first barrier metal portion 61 is thinned, the oxide layer 66 may be formed on the upper surface of the first alloy layer 63. In the semiconductor device 100, removing the oxide layer 66 can decrease a resistance in the contact hole 54. In the semiconductor device 100 in the present example, it is possible to suppress the variation in the threshold voltage while decreasing the resistance in the contact hole 54. In addition, in the semiconductor device 100, since it is possible to form the lifetime control region while suppressing the variation in the threshold voltage, a reverse recovery loss can be reduced.

It is to be noted that although an influence of the electron beams and particle beams for forming the lifetime control region on the MOS gate structure is greater when irradiating the beams from a front surface 21 side of the semiconductor substrate 10, the beams may affect the MOS gate structure also when being irradiated from a back surface 23 side of the semiconductor substrate 10. Thus, also when irradiating from the back surface 23 side, the semiconductor device 100 can recover the damage of the MOS gate structure and suppress the variation of the threshold voltage. It is to be noted that although an acceleration voltage becomes large to result in an increase in the size of the device when irradiating particle beams and the like from the back surface 23 side of the semiconductor substrate 10, in the semiconductor device 100 in the present example, the effect of irradiating particle beams and the like from the front surface 21 can be suppressed, and thus the lifetime control region can be formed with a more compact device.

The first conductivity type region 161 is a region of a first conductivity type which is provided at the front surface 21 of the semiconductor substrate 10 and has a higher doping concentration than a drift region 18. The first conductivity type region 161 may be an N type region in a transistor portion 70. The first conductivity type region 161 in the present example is the emitter region 12, but it is not limit thereto. The first conductivity type region 161 may be an N type region in a MOSFET. The first conductivity type region 161 may be an N type region provided in a region other than the transistor portion 70. The first conductivity type region 161 may be an N type region in a temperature sensing diode. The first conductivity type region 161 may be an N type region in a diode portion such as an RC-IGBT.

FIG. 3B is an enlarged view of a cross section of a semiconductor device 100. The cross section in the present example is different from the cross section in FIG. 3A in that it passes through a contact region 15 at a front surface 21. The contact region 15 is one example of a second conductivity type region 162. In the present example, difference with FIG. 3A will be particularly described.

The second conductivity type region 162 is a region of a second conductivity type which is provided at the front surface 21 of the semiconductor substrate 10. The second conductivity type region 162 may be a P type region in a transistor portion 70. The second conductivity type region 162 in the present example is the contact region 15, but it is not limited thereto. The second conductivity type region 162 may be a P type region in a MOSFET. The second conductivity type region 162 may be a P type region provided in a region other than the transistor portion 70. The second conductivity type region 162 may be a P type region in a temperature sensing diode. The second conductivity type region 162 may be a P type region in a diode portion such as an RC-IGBT.

A structure of a contact hole 54 above the second conductivity type region 162 may be the same as or different from a structure of the contact hole 54 above the first conductivity type region 161. That is, the film thickness of the barrier metal layer 60 and the film thickness of the first alloy layer 63 above the first conductivity type region 161 may be respectively the same as a film thickness of a barrier metal layer 60 and a film thickness of a first alloy layer 63 above the second conductivity type region 162. A P type region including the second conductivity type region 162 may be formed such that a concentration of a P type impurity is high at a place in contact with the first alloy layer 63, thereby reducing a contact resistance.

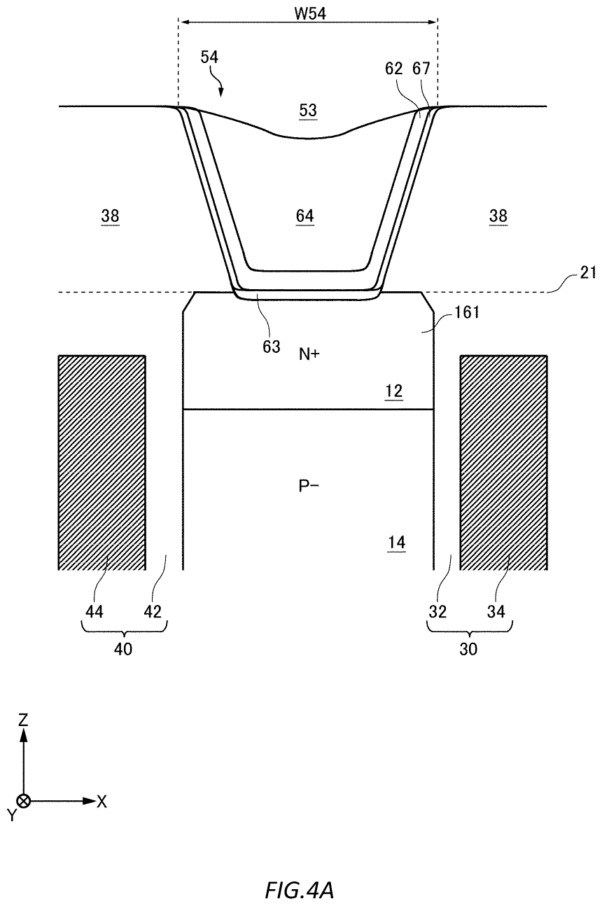

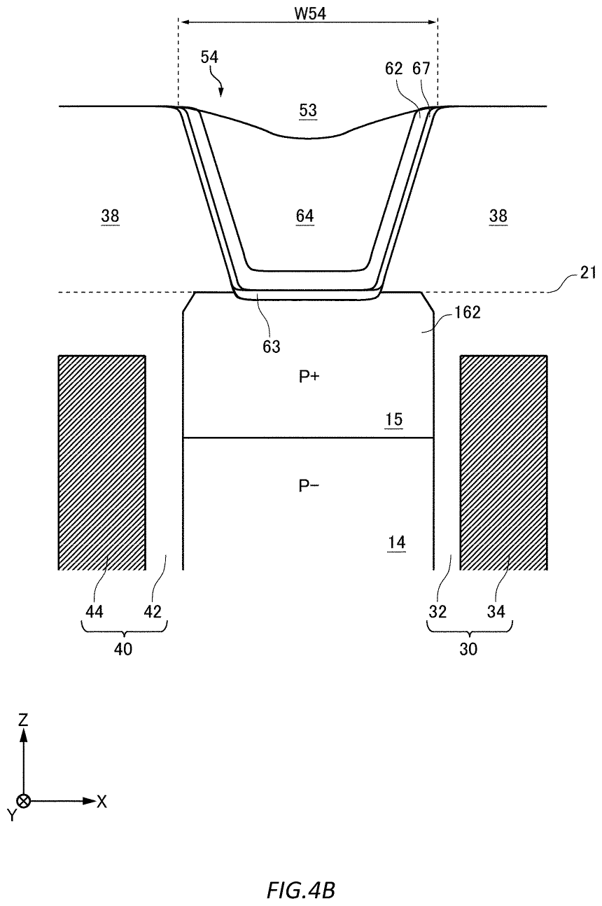

FIG. 4A is an enlarged view of a cross section of a semiconductor device 100 as a modified example. The cross section in the present example is the XZ cross section which passes through an emitter region 12 at a front surface 21 of a semiconductor substrate 10. The semiconductor device 100 in the present example is different from the one in the embodiment example in FIG. 3A in that it does not include a first barrier metal portion 61 and includes an initial metal film 67 between a second barrier metal portion 62 and an interlayer dielectric film 38.

The initial metal film 67 may remain in a process of forming a first alloy layer 63. The initial metal film 67 may be denser than the second barrier metal portion 62. The initial metal film 67 is provided on side walls of the interlayer dielectric film 38 in a contact hole 54. The initial metal film 67 may be provided in contact with an upper surface of the interlayer dielectric film 38. The second barrier metal portion 62 is provided on a bottom surface of the contact hole 54 and on the side walls of the interlayer dielectric film 38. The second barrier metal portion 62 may be provided above the interlayer dielectric film 38, and the initial metal film 67 may be provided between the second barrier metal portion 62 and the interlayer dielectric film 38. The second barrier metal portion 62 in the present example is provided on an upper surface of the first alloy layer 63 and on the side walls of the interlayer dielectric film 38 in the contact hole 54, and the initial metal film 67 is provided between the side walls of the interlayer dielectric film 38 and the second barrier metal portion 62.

The first barrier metal portion 61 may not be formed, or may be formed. When the first barrier metal portion 61 is formed, the first barrier metal portion 61 may be completely removed after the first barrier metal portion 61 is formed on a surface of the initial metal film 67 through annealing treatment performed in the process of forming the first alloy layer 63.

FIG. 4B is an enlarged view of a cross section of a semiconductor device 100 as a modified example. The cross section in the present example is the XZ plane which passes through a contact region 15 at a front surface 21 of a semiconductor substrate 10. The semiconductor device 100 in the present example is different from the one in the embodiment example in FIG. 3B in that it does not include a first barrier metal portion 61 and includes an initial metal film 67 between a second barrier metal portion 62 and an interlayer dielectric film 38.

In the embodiment examples in FIG. 4A and FIG. 4B as well, thinning the initial metal film 67 can reduce a remaining amount of a first metal having a hydrogen absorbing effect. This can suppress an influence of the hydrogen absorbing effect and promote hydrogen termination of a dangling bond in a MOS gate structure. Accordingly, a variation in a threshold voltage can be suppressed.

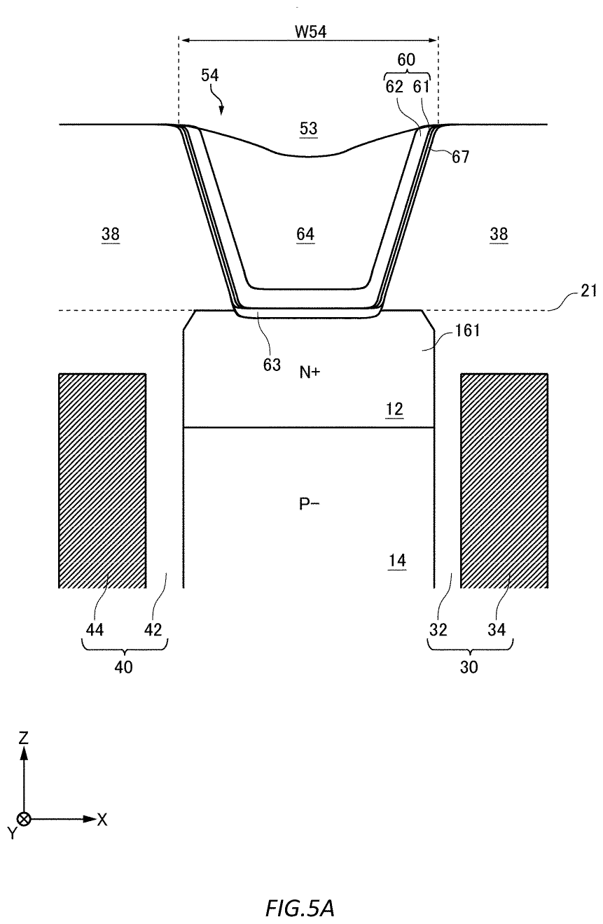

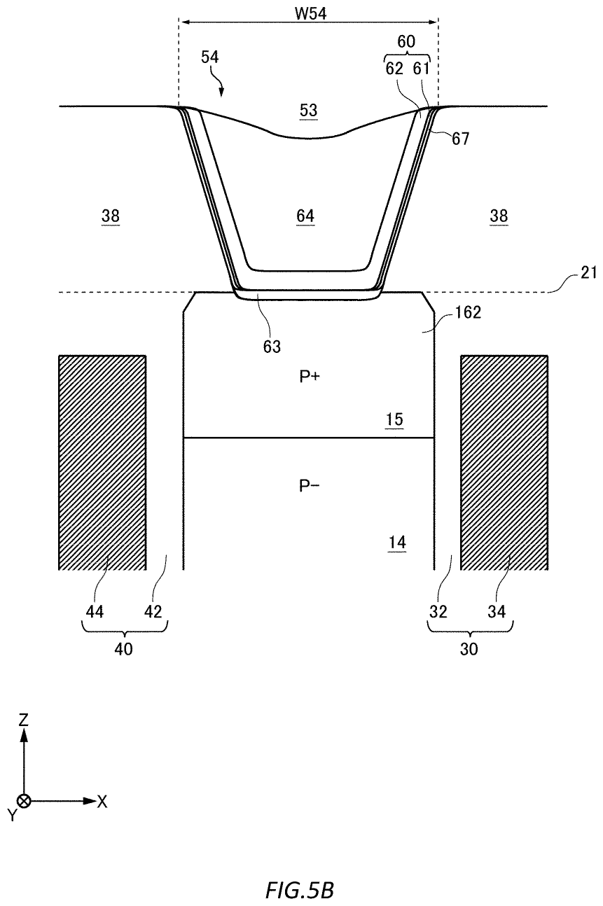

FIG. 5A is an enlarged view of a cross section of a semiconductor device 100 as a modified example. The cross section in the present example is the XZ cross section which passes through an emitter region 12 at a front surface 21 of a semiconductor substrate 10. The semiconductor device 100 in the present example is different from the one in the embodiment example in FIG. 3A in that it includes an initial metal film 67 between a first barrier metal portion 61 and an interlayer dielectric film 38.

In the present example, the first barrier metal portion 61 is formed through annealing treatment performed in a process of forming a first alloy layer 63, and the initial metal film 67 remains. The first barrier metal portion 61 may partially remains even after etching. The initial metal film 67 is provided on side walls of the interlayer dielectric film 38 in a contact hole 54. The initial metal film 67 may be provided in contact with an upper surface of the interlayer dielectric film 38. A barrier metal layer 60 is provided on a bottom surface of the contact hole 54 and on the side walls of the interlayer dielectric film 38. The barrier metal layer 60 may be provided above the interlayer dielectric film 38, and the initial metal film 67 may be provided between the barrier metal layer 60 and the interlayer dielectric film 38. The barrier metal layer 60 in the present example is provided on an upper surface of the first alloy layer 63 and on the side walls of the interlayer dielectric film 38 in the contact hole 54, and the initial metal film 67 is provided between the side walls of the interlayer dielectric film 38 and the barrier metal layer 60.

FIG. 5B is an enlarged view of a cross section of a semiconductor device 100. The cross section in the present example is the XZ plane which passes through a contact region 15 at a front surface 21 of a semiconductor substrate 10. The semiconductor device 100 in the present example is different from the one in the embodiment example in FIG. 3B in that it includes an initial metal film 67 between a first barrier metal portion 61 and an interlayer dielectric film 38.

In the embodiment examples in FIG. 5A and FIG. 5B as well, the first barrier metal portion 61 being thinned by etching can suppress an influence of a hydrogen absorbing effect and promote hydrogen termination of a dangling bond in a MOS gate structure. Accordingly, a variation in a threshold voltage can be suppressed.

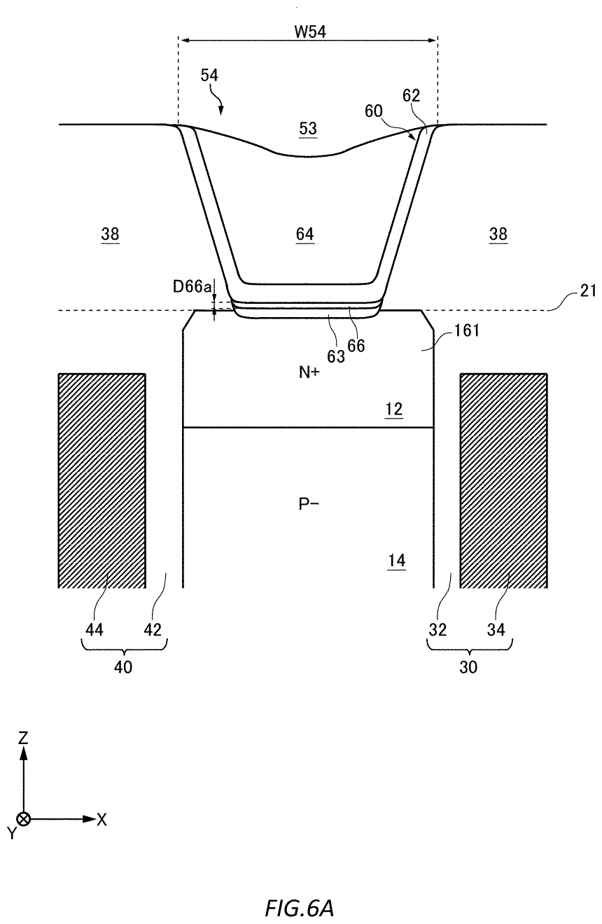

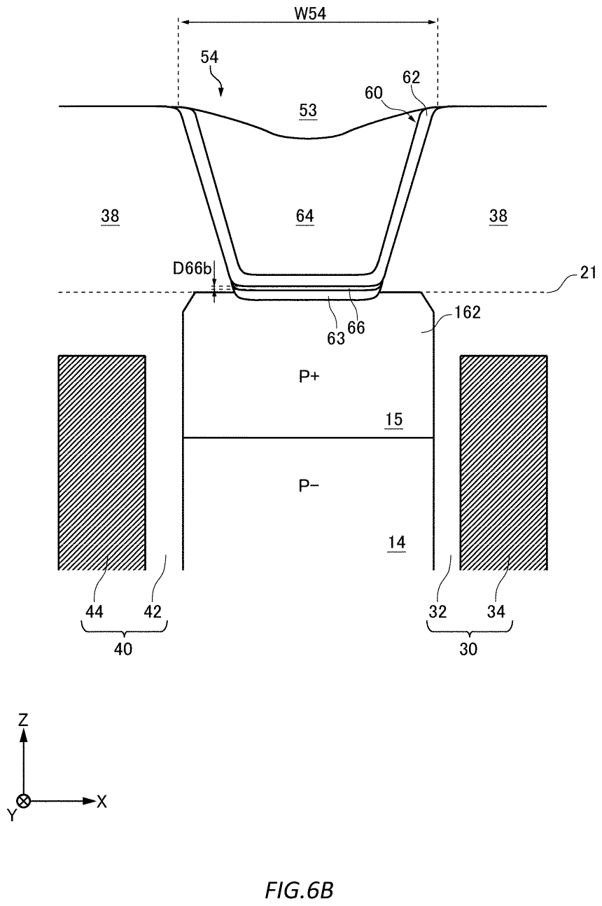

FIG. 6A is an enlarged view of a cross section of a semiconductor device 100 as a modified example. In the present example, the enlarged view of the cross section in the vicinity of a contact hole 54 is shown. The cross section in the present example is the XZ cross section which passes through an emitter region 12 at a front surface 21 of a semiconductor substrate 10. The present example is different from the embodiment example in FIG. 3A in that an oxide layer 66 is provided. The semiconductor device 100 in the present example is different from the one in the embodiment example in FIG. 3A in that it does not include a first barrier metal portion 61.

The oxide layer 66 is provided on an upper surface of a first alloy layer 63 in the contact hole 54. The oxide layer 66 may be in contact with the upper surface of the first alloy layer 63, or may be in contact with a lower surface of a barrier metal layer 60. The oxide layer 66 may be provided in contact with the first alloy layer 63 and the barrier metal layer 60. That is, the oxide layer 66 may be provided so as to be stacked between the first alloy layer 63 and the barrier metal layer 60. It is to be noted that, when the first barrier metal portion 61 is formed on the first alloy layer 63, or when an initial metal film 67 remains on the first alloy layer 63, the oxide layer 66 may be formed on the first barrier metal portion 61 or the initial metal film 67. In addition, the oxide layer 66 may be formed on side walls of an interlayer dielectric film 38 and under a second barrier metal portion 62 in the contact hole 54.

The oxide layer 66 may contain an element constituting the first alloy layer 63, the first barrier metal portion 61, or the initial metal film 67. The oxide layer 66 may contain an oxide of silicon or an element constituting the semiconductor substrate 10. For example, the oxide layer 66 is a silicon oxide film. Composition of the oxide layer 66 may be at least one of SiO, SiO₂, or Si₂O₃. The oxide layer 66 may contain a predetermined conductive first metal. For example, the oxide layer 66 may contain titanium, or may include a titanium oxide film. The composition of the oxide layer 66 may be at least one of TiO, TiO₂, or Ti₂O₃. The oxide layer 66 may be a dense film that functions as a metal diffusion preventing layer. For example, the oxide layer 66 can prevent diffusion of a plug layer 64 during formation of the plug layer 64, and protect the first alloy layer 63 from damage caused during the formation of the plug layer 64.

A film thickness of the oxide layer 66 may be smaller than a film thickness of the first alloy layer 63. The film thickness of the oxide layer 66 may be smaller than a film thickness of the second barrier metal portion 62. The film thickness of the oxide layer 66 may be 0.5 nm or more and 4.0 nm or less. For example, the film thickness of the oxide layer 66 is 2.5 nm. The film thickness of the oxide layer 66 may be a film thickness at a position where the oxide layer 66 is the thickest in the contact hole 54.

A film thickness D66a is a thickness of the oxide layer 66 in a depth direction of the semiconductor substrate 10 above a first conductivity type region 161. The film thickness D66a may be a film thickness of the oxide layer 66 at the position where the oxide layer 66 is the thickest. The film thickness D66a may be smaller than the film thickness of the first alloy layer 63.

The oxide layer 66 may be formed through chemical exposure such as etching. The oxide layer 66 may be formed by etching an upper surface of the first alloy layer 63, the first barrier metal portion 61, or the initial metal film 67. The upper surface of the first alloy layer 63 may be etched by wet etching or dry etching. The oxide layer 66 may be formed by dry etching the upper surface of the first alloy layer 63, the first barrier metal portion 61, or the initial metal film 67. In addition, the oxide layer 66 may be formed by oxidizing the upper surface of the first alloy layer 63, the first barrier metal portion 61, or the initial metal film 67. The oxide layer 66 may be formed by annealing the semiconductor substrate 10 in an oxygen atmosphere. The oxide layer 66 may be formed by being deposited on the first alloy layer 63, the first barrier metal portion 61, the initial metal film 67, or the interlayer dielectric film 38.

The barrier metal layer 60 includes the second barrier metal portion 62. The barrier metal layer 60 may not include the first barrier metal portion 61. The first barrier metal portion 61 formed during formation of the first alloy layer 63, and/or the initial metal film 67 which has remained without the first barrier metal portion 61 being formed during the formation of the first alloy layer 63, may be removed by etching. The second barrier metal portion 62 in the present example may be provided in contact with the side walls of the interlayer dielectric film 38.

In the semiconductor device 100 in the present example, providing the oxide layer 66 as the metal diffusion preventing layer can ensure barrier properties during film formation of the plug layer 64. In the semiconductor device 100, it may be determined whether the oxide layer 66 should be provided for each contact hole, and the film thickness of the oxide layer 66 may be changed as appropriate.

FIG. 6B is an enlarged view of a cross section of a semiconductor device 100 as a modified example. The cross section in the present example is different from the cross section in FIG. 6A in that it passes through a contact region 15 at a front surface 21. In the present example, difference with FIG. 6A will be particularly described.

A film thickness D66b is a thickness of an oxide layer 66 in a depth direction of a semiconductor substrate 10. In particular, the film thickness D66b is the thickness of the oxide layer 66 in the depth direction of the semiconductor substrate 10 above a second conductivity type region 162. The film thickness D66b may be smaller than a film thickness of a first alloy layer 63. The film thickness D66b of the oxide layer 66 above the second conductivity type region 162 in the present example is smaller than the film thickness D66a of the oxide layer 66 above the first conductivity type region 161.

The oxide layers 66 may be selectively etched above the second conductivity type region 162 after being formed above the first conductivity type region 161 and the second conductivity type region 162. A mask may be used to form the oxide layers 66 separately above the first conductivity type region 161 and above the second conductivity type region 162 and provide the oxide layers 66 having different film thicknesses. The film thickness of the oxide layer 66 may be greater above the first conductivity type region 161 than above the second conductivity type region 162. In the present example, although a thickness of the oxide layer 66 above the second conductivity type region 162 is smaller than a thickness of the oxide layer 66 above the first conductivity type region 161, the thickness of the oxide layer 66 above the first conductivity type region 161 may be smaller than the thickness of the oxide layer 66 above the second conductivity type region 162.

In the semiconductor device 100 in the present example, etching the oxide layer 66 above the contact region 15 can improve hole extraction and facilitate suppression of latch-up. In the semiconductor device 100, damage caused during formation of a plug layer 64 can be reduced by leaving the oxide layer 66 above the semiconductor substrate 10.

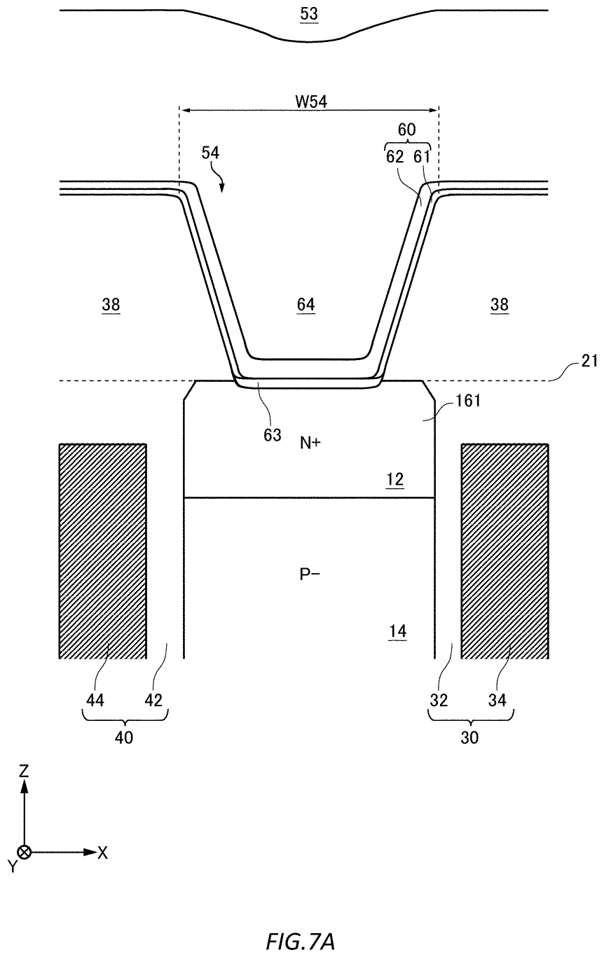

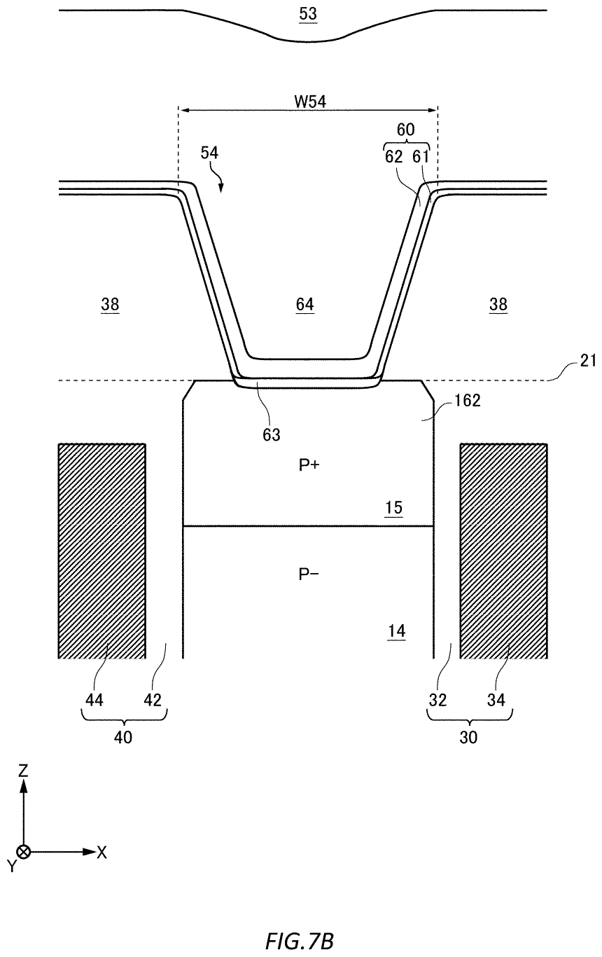

FIG. 7A is an enlarged view of a cross section of a semiconductor device 100 as a modified example. The cross section in the present example is the XZ cross section which passes through an emitter region 12 at a front surface 21 of a semiconductor substrate 10. The semiconductor device 100 in the present example is different from the one in the embodiment example in FIG. 3A in that a barrier metal layer 60 and a plug layer 64 are provided above an interlayer dielectric film 38 outside a contact hole 54.

The barrier metal layer 60 may be provided in contact with an upper surface of the interlayer dielectric film 38 outside the contact hole 54. The plug layer 64 may be provided in contact with a second barrier metal portion 62 and above the interlayer dielectric film 38 outside the contact hole 54. It should be noted that only the barrier metal layer 60 may be provided outside the contact hole 54 and the plug layer 64 may be formed only inside the contact hole 54. Forming the barrier metal layer 60 and the plug layer 64 on the interlayer dielectric film 38 as well can improve reliability during implementation of wire bonding, resin sealing, or the like. In addition, the barrier metal layer 60 may not include a first barrier metal portion 61 formed outside or inside the contact hole 54, and an initial metal film 67 may be formed between the barrier metal layer 60 and the interlayer dielectric film 38. As one example, the barrier metal layer 60 may not be provided with the first barrier metal portion 61 and may be provided with only the second barrier metal portion 62 inside and outside the contact hole 54, and the plug layer 64 may be provided only inside the contact hole 54.

FIG. 7B is an enlarged view of a cross section of a semiconductor device 100 as a modified example. The cross section in the present example is the XZ plane which passes through a contact region 15 at a front surface 21 of a semiconductor substrate 10. The semiconductor device 100 in the present example is different from the one in the embodiment example in FIG. 3B in that a barrier metal layer 60 and a plug layer 64 are provided above an interlayer dielectric film 38 outside a contact hole 54. In the embodiment examples in FIG. 7A and FIG. 7B as well, in the semiconductor device 100, removing or thinning a first barrier metal portion 61 or/and an initial metal film 67 by etching can suppress an influence of a hydrogen absorbing effect and promote hydrogen termination of a dangling bond in a MOS gate structure. Accordingly, a variation in a threshold voltage can be suppressed.

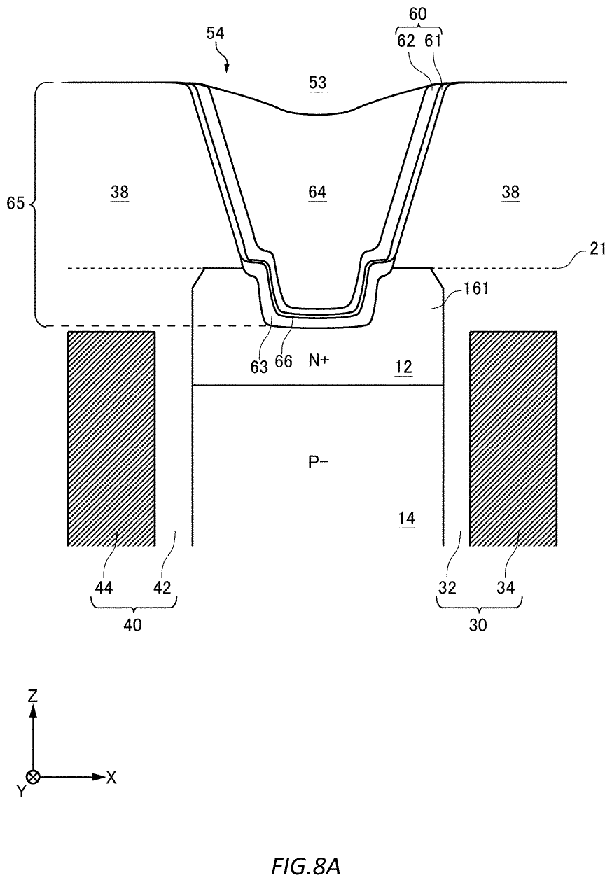

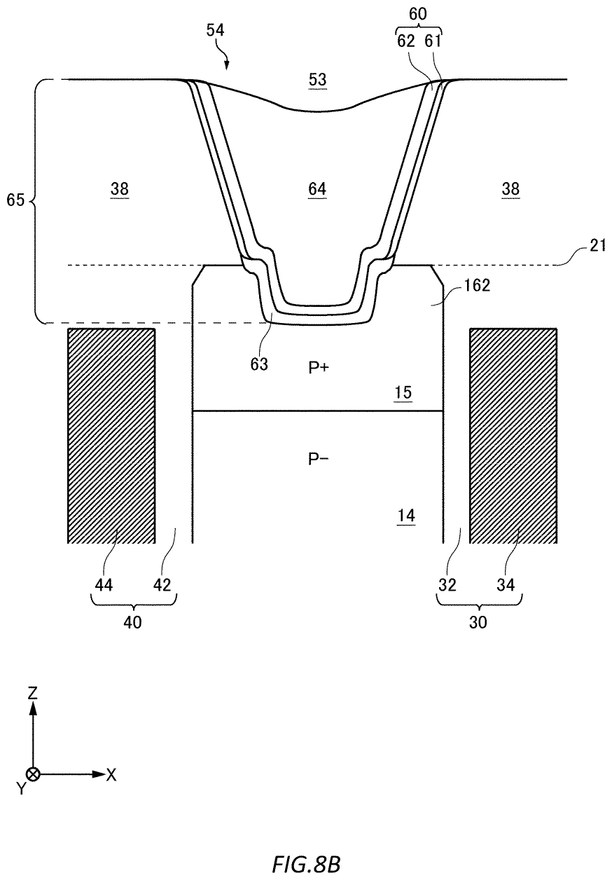

FIG. 8A is an enlarged view of a cross section of a semiconductor device 100 as a modified example. In the present example, the enlarged view of the cross section in the vicinity of a contact hole 54 is shown. The cross section in the present example is the XZ cross section which passes through an emitter region 12 at a front surface 21 of a semiconductor substrate 10. The semiconductor device 100 in the present example is different from the one in the embodiment example in FIG. 6A in that it includes a trench contact portion 65.

The trench contact portion 65 includes the contact hole 54, and is provided extending from the front surface 21 of the semiconductor substrate 10 in a depth direction of the semiconductor substrate 10. A lower end of the trench contact portion 65 in the present example is at a position upper than that of a lower end of the emitter region 12. The lower end of the trench contact portion 65 may be at a position lower than that of the lower end of the emitter region 12. The lower end of the trench contact portion 65 in the present example is at a position upper than that of an upper end of a gate conductive portion 44. The lower end of the trench contact portion 65 may be at a position lower than that of the upper end of the gate conductive portion 44.

A barrier metal layer 60 may include a first barrier metal portion 61 and a second barrier metal portion 62 in the trench contact portion 65. It should be noted that the first barrier metal portion 61 may be removed and only the second barrier metal portion 62 may be provided. The first barrier metal portion 61 is provided in contact with side walls of an interlayer dielectric film 38. The first barrier metal portion 61 may not be provided below the front surface 21. A first alloy layer 63 is provided in contact with side walls of the semiconductor substrate 10 and an upper surface of the semiconductor substrate 10 in the trench contact portion 65.

An oxide layer 66 is in contact with the first alloy layer 63. The oxide layer 66 is provided so as to be stacked on the first alloy layer 63. The oxide layer 66 is provided on an upper surface and a side surface of the first alloy layer 63 in the trench contact portion 65. The oxide layer 66 may be provided on the entire exposed surface of the first alloy layer 63 during formation of the oxide layer 66.

The barrier metal layer 60 is provided in contact with the oxide layer 66 provided on the side walls of the semiconductor substrate 10. The second barrier metal portion 62 in the present example is provided in contact with the first barrier metal portion 61 and the oxide layer 66. The second barrier metal portion 62 is provided so as to be stacked on the first barrier metal portion 61 provided on the side walls of the interlayer dielectric film 38. A plug layer 64 is provided farther inward than the second barrier metal portion 62 in the contact hole 54.

It is to be noted that, although the interlayer dielectric film 38 in the present example includes one layer of dielectric film, it may have a stacked structure in which a plurality of dielectric films are stacked. In the semiconductor device 100 in the present example, providing the trench contact portion 65 can increase a contact area with the semiconductor substrate 10 and reduce a contact resistance. Providing the trench contact portion 65 in a transistor portion 70 can facilitate hole extraction and suppress latch-up.

It is to be noted that, although the semiconductor device 100 in the present example includes the oxide layer 66 in the trench contact portion 65 above a first conductivity type region 161, the oxide layer 66 may be removed by etching. The oxide layer 66 may be thinned or completely removed by etching.

FIG. 8B is an enlarged view of a cross section of a semiconductor device 100 as a modified example. The cross section in the present example is different from the cross section in FIG. 8A in that it passes through a contact region 15 at a front surface 21. In the present example, difference with FIG. 8A will be particularly described.

An oxide layer 66 is provided above a first conductivity type region 161, and is not provided above a second conductivity type region 162. That is, the oxide layer 66 may not be provided above the contact region 15. The oxide layer 66 may be selectively removed above the second conductivity type region 162 after being formed above the first conductivity type region 161 and the second conductivity type region 162. The oxide layer 66 may not be formed above the second conductivity type region 162 and may be formed only above the first conductivity type region 161 by using a mask.

In the semiconductor device 100 in the present example, removing the oxide layer 66 above the contact region 15 can improve hole extraction and facilitate suppression of latch-up. In the semiconductor device 100, damage caused during formation of a plug layer 64 can be reduced by providing the oxide layer 66 above an emitter region 12.

In the present example, the oxide layer 66 is omitted above the second conductivity type region 162 in the semiconductor device 100 which includes a trench contact portion 65, but the oxide layer 66 may be similarly omitted or provided in the semiconductor device 100 which does not include the trench contact portion 65. That is, in any of the embodiment examples in FIG. 3A, FIG. 3B, FIG. 4A, FIG. 4B, FIG. 5A, FIG. 5B, FIG. 6A, FIG. 6B, FIG. 7A, and FIG. 7B, the oxide layer 66 may be omitted or provided. In addition, in the present example, the oxide layer 66 above the second conductivity type region 162 is omitted, but the oxide layer 66 above the first conductivity type region 161 may be omitted. In addition, in the present example as well, a thickness of the oxide layer 66 above the first conductivity type region 161 may be the same as or different from a thickness of the oxide layer 66 above the second conductivity type region 162.

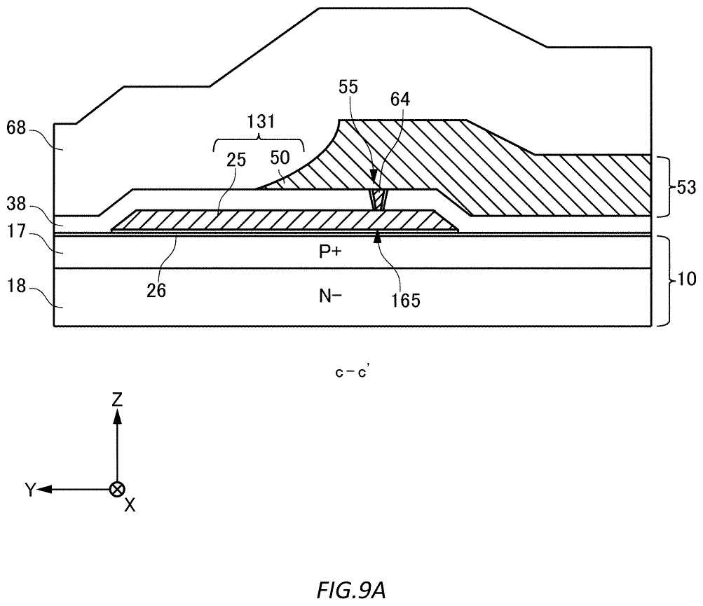

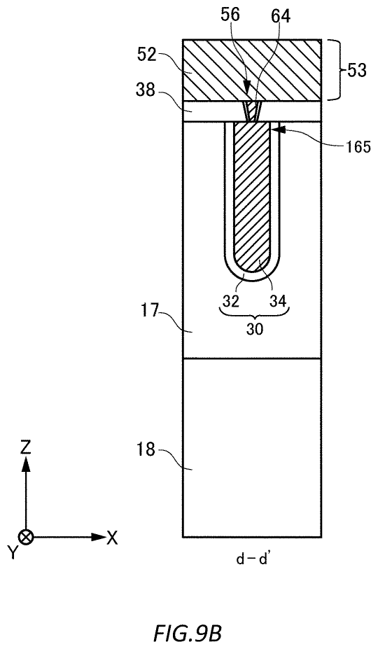

FIG. 9A shows one example of a cross section c-c′ in FIG. 1A or FIG. 2B. The cross section c-c′ is the YZ plane which passes through a gate runner between active portions 131. The gate runner between active portions 131 in the present example includes a gate metal layer 50 and a connection portion 25. The gate metal layer 50 is one example of a front surface side metal layer 53. The connection portion 25 is one example of a polycrystalline layer 165. The polycrystalline layer 165 is a polycrystalline layer provided above or inside a semiconductor substrate 10, and may be a semiconductor or may be a metal. The polycrystalline layer 165 in the present example is a polysilicon layer. As another example, when the semiconductor substrate 10 is a silicon carbide substrate, the polycrystalline layer 165 may be a polycrystalline layer containing silicon carbide; when the semiconductor substrate 10 is a gallium nitride substrate, the polycrystalline layer 165 may be a polycrystalline layer containing gallium nitride; and when the semiconductor substrate 10 is a diamond substrate, the polycrystalline layer 165 may be a polycrystalline layer containing diamond. A covering layer 68 made of polyimide or the like may be provided above the gate runner between active portions 131.

The polycrystalline layer 165 may be provided above the semiconductor substrate 10. The polycrystalline layer 165 is electrically connected to a gate conductive portion 44. It is to be noted that the polycrystalline layer 165 may be omitted, and only the front surface side metal layer 53 may function as the gate runner between active portions 131. In addition, the front surface side metal layer 53 above the polycrystalline layer 165 may be omitted, and only the polycrystalline layer 165 may function as the gate runner between active portions 131. It is to be noted that, in the present example, the cross section of the gate runner between active portions 131 has been described, but the front surface side metal layer 53 and the polycrystalline layer 165 may be similarly provided for an outer circumferential gate runner 130.

The front surface side metal layer 53 is provided via a dielectric film 26 above the semiconductor substrate 10. Part of the front surface side metal layer 53 may be provided so as to overlap the polycrystalline layer 165 in a depth direction of the semiconductor substrate 10. The front surface side metal layer 53 in the present example is electrically connected to the polycrystalline layer 165 via a contact hole 55 provided above the polycrystalline layer 165. The front surface side metal layer 53 may be formed of the same material as that of an emitter electrode 52, or may be formed of a different material from that of the emitter electrode 52.

The contact hole 55 may be provided with a barrier metal layer 60, a first alloy layer 63, and a plug layer 64. As disclosed in any of the embodiment examples in FIG. 6A, FIG. 6B, and FIG. 8A, in the contact hole 55, an oxide layer 66 may be formed on an upper surface of the polycrystalline layer 165. In the contact hole 55, the oxide layer 66 on the upper surface of the polycrystalline layer 165 may be etched. In the contact hole 55, the oxide layer 66 may be removed by etching, or the oxide layer 66 may be left without being removed by etching. In the contact hole 55, the oxide layer 66 which is thinner than the one in another contact hole such as a contact hole 54 may be left.

The contact hole 55 may be provided with the barrier metal layer 60, the first alloy layer 63, the plug layer 64, the oxide layer 66, and an initial metal film 67, as disclosed in any of the embodiment examples in FIG. 3A, FIG. 3B, FIG. 4A, FIG. 4B, FIG. 5A, FIG. 5B, FIG. 6A, FIG. 6B, FIG. 7A, and FIG. 7B. In the contact hole 55, a gate resistance of a semiconductor device 100 can be adjusted by changing presence or absence of the oxide layer 66 or changing a film thickness of the oxide layer 66. Magnitude of the gate resistance of the semiconductor device 100 may be adjusted by providing a resistive layer in stead of the oxide layer 66.

The film thickness of the oxide layer 66 may be smaller above the polycrystalline layer 165 than above the first alloy layer 63 on mesa portions 71, 81, and 91 and the semiconductor substrate 10. The oxide layer 66 may be omitted in the contact hole 55 provided above the polycrystalline layer 165. The film thickness of the oxide layer 66 may be greater above the polycrystalline layer 165 than above the first alloy layer 63 on the mesa portions 71, 81, and 91 and the semiconductor substrate 10. The oxide layer 66 may be provided in the contact hole 55 provided above the polycrystalline layer 165, and may be omitted above the first alloy layer 63 on the mesa portions 71, 81, and 91 and the semiconductor substrate 10. The magnitude of the gate resistance of the semiconductor device 100 can be adjusted by changing the film thickness of the oxide layer 66 above the polycrystalline layer 165. In addition, it may be adjusted, depending on the magnitude of the gate resistance of the semiconductor device 100, whether the oxide layer 66 should be provided above the polycrystalline layer 165. The magnitude of the gate resistance of the semiconductor device 100 may be adjusted by changing an area of the contact hole 55 in addition to the film thickness of the oxide layer 66. The magnitude of the gate resistance of the semiconductor device 100 may be adjusted by providing the resistive layer in stead of the oxide layer 66.

It is to be noted that a contact hole 58 may be provided in the gate runner between active portions 131. That is, the contact hole 58 may function as a contact hole for connecting the front surface side metal layer 53 provided in the gate runner between active portions 131 and the polycrystalline layer 165. In the gate runner between active portions 131 as well, the magnitude of the gate resistance may be adjusted depending on greatness of the film thickness of the oxide layer 66, the presence or absence of the oxide layer 66, presence or absence of the resistive layer, and an area of the contact hole 58.

FIG. 9B shows one example of a cross section d-d′ in FIG. 1A or FIG. 2B. The cross section d-d′ is the XZ plane which passes through a dummy trench portion 30.

A polycrystalline layer 165 may be provided in a semiconductor substrate 10. A dummy conductive portion 34 in the present example is one example of the polycrystalline layer 165 provided in the semiconductor substrate 10. A contact hole 56 may be provided above the dummy conductive portion 34. The contact hole 56 functions as a contact hole for connecting an emitter electrode 52 and the polycrystalline layer 165. The emitter electrode 52 is one example of a front surface side metal layer 53. In the present example, presence or absence of an oxide layer 66, greatness of a film thickness of the oxide layer 66, and an area of the contact hole 56 may be adjusted as appropriate.

The contact hole 56 may be provided with a barrier metal layer 60, a first alloy layer 63, a plug layer 64, and the oxide layer 66. The contact hole 56 may be provided with the barrier metal layer 60, the first alloy layer 63, the plug layer 64, and the oxide layer 66, as disclosed in any of the embodiment examples in FIG. 6A, FIG. 6B, and FIG. 8A. The contact hole 56 may be provided with an initial metal film 67, as disclosed in any of the embodiment examples in FIG. 4A, FIG. 4B, FIG. 5A, and FIG. 5B. The contact hole 56 may not be provided with the oxide layer 66, as disclosed in any of the embodiment examples in FIG. 3A, FIG. 3B, FIG. 4A, FIG. 4B, FIG. 5A, FIG. 5B, FIG. 7A, FIG. 7B, and FIG. 8B. In FIG. 1A, FIG. 2B, FIG. 9A, and FIG. 9B, a gate conductive portion 44 and the front surface side metal layer 53 are connected via a connection portion 25 and a contact hole 55, and the dummy conductive portion 34 and the emitter electrode 52 are connected via the contact hole 56. The gate conductive portion 44 and the front surface side metal layer 53 may be connected via the contact hole 55, and the dummy conductive portion 34 and the emitter electrode 52 may be connected via the connection portion 25 and the contact hole 56.

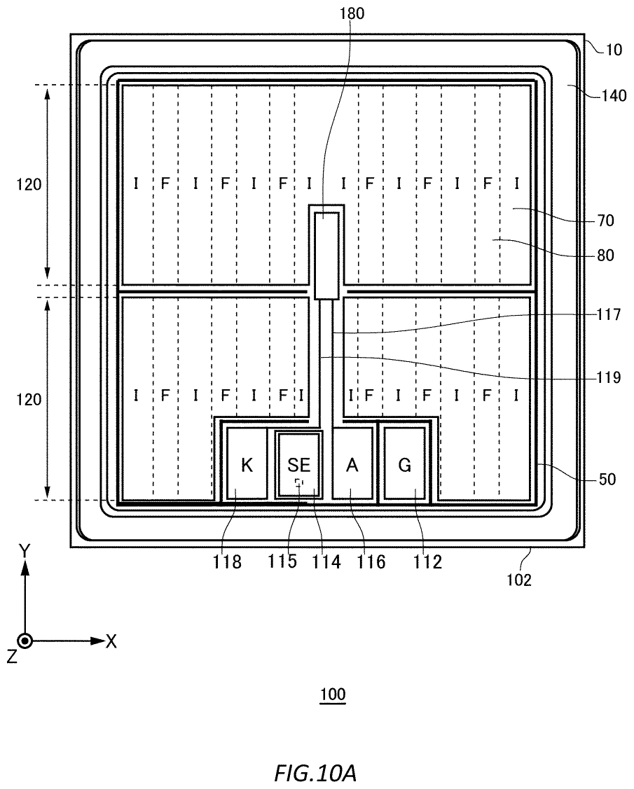

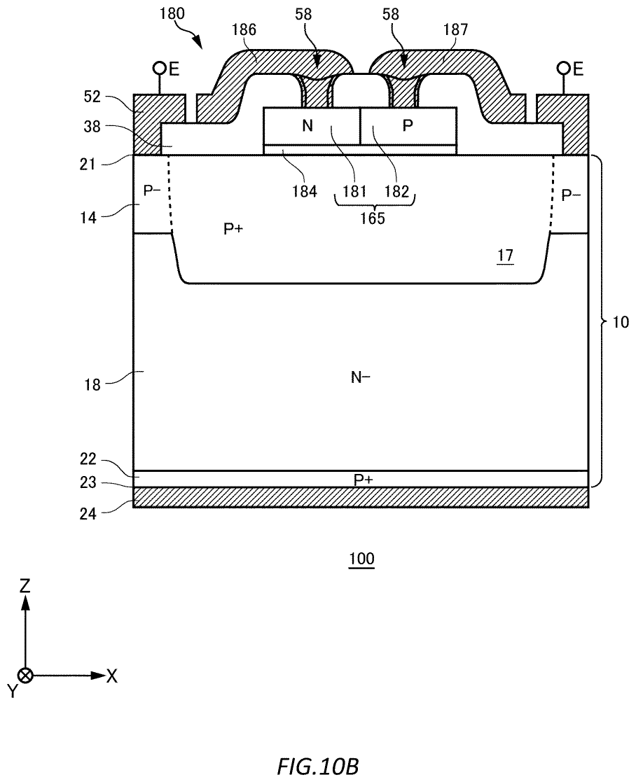

FIG. 10A shows one example of a top view of a semiconductor device 100 including a temperature sensing unit 180. The semiconductor device 100 in the present example includes a gate pad 112, a sensing electrode 114, an anode pad 116, and a cathode pad 118.

A front surface side metal layer 53 may include the gate pad 112, the sensing electrode 114, the anode pad 116, and the cathode pad 118. The front surface side metal layer 53 may be electrically connected to a conductive member such as a lead frame. The front surface side metal layer 53 may be electrically connected to an electrode external to the semiconductor device 100 by wire bonding or the like. It is to be noted that the number of front surface side metal layers 53 and a position of the front surface side metal layer 53 are not limited to the present example.

The sensing electrode 114 is electrically connected to a current sensing unit 115 provided below the sensing electrode 114. The sensing electrode 114 detects a current flowing through the current sensing unit 115. The current sensing unit 115 detects a current flowing through a transistor portion 70. The current sensing unit 115 has a structure corresponding to the transistor portion 70, simulates operation of the transistor portion 70, and allows a current proportional to the current flowing through the transistor portion 70, to flow therethrough. The current flowing through the transistor portion 70 can be monitored by using the current sensing unit 115.

The temperature sensing unit 180 is provided on top of or inside a semiconductor substrate 10. In the present example, it is provided on a well region 17 between transistor portions 70 in a central portion of the semiconductor device 100. The temperature sensing unit 180 detects a temperature of an active portion 120. The temperature sensing unit 180 may include a diode formed of monocrystalline or polycrystalline silicon. The temperature sensing unit 180 is used to detect a temperature of the semiconductor device 100 and protect a semiconductor chip from overheating. The temperature sensing unit 180 is connected to a constant-current source. When the temperature of the semiconductor device 100 changes, a forward voltage of a current flowing through the temperature sensing unit 180 changes. The semiconductor device 100 can detect a temperature based on a change in the forward voltage of the temperature sensing unit 180. The temperature sensing unit 180 has a longitudinal direction in the Y axis direction and has a lateral direction in the X axis direction, but it is not limited thereto.

The anode pad 116 is electrically connected to an anode region of the temperature sensing unit 180. The anode pad 116 is electrically connected to the anode region of the temperature sensing unit 180 by an anode wiring line 117.

The cathode pad 118 is electrically connected to a cathode region of the temperature sensing unit 180. The cathode pad 118 is electrically connected to the cathode region of the temperature sensing unit 180 by a cathode wiring line 119.

FIG. 10B is one example of an enlarged view of a cross section in a temperature sensing unit 180. Although the temperature sensing unit 180 in the present example includes a contact hole 58, to which a structure of any contact hole in another embodiment example may be applied.

The temperature sensing unit 180 includes a diode provided in a semiconductor substrate 10. The temperature sensing unit 180 detects a temperature of a semiconductor device 100 by utilizing the fact that current-voltage characteristics of the diode change depending on a temperature. The temperature sensing unit 180 is arranged above the semiconductor substrate 10 via an interlayer dielectric film 184. The interlayer dielectric film 184 may be an HTO film. The temperature sensing unit 180 may be provided above a well region 17. The temperature sensing unit 180 in the present example includes a cathode region 181, an anode region 182, the interlayer dielectric film 184, a cathode electrode 186, and an anode electrode 187.

The cathode region 181 and the anode region 182 constitute a PN diode. For example, the cathode region 181 is formed of an N type semiconductor, and functions as a cathode of the PN diode. The anode region 182 is formed of a P type semiconductor, and functions as an anode of the PN diode. The cathode region 181 and the anode region 182 are provided on the interlayer dielectric film 184. A material of the cathode region 181 and the anode region 182 may be polysilicon.

The cathode region 181 and the anode region 182 are examples of a polycrystalline layer 165. That is, in the contact hole 58, an oxide layer 66 may be provided or may not be provided above the cathode region 181 and the anode region 182. The oxide layer 66 may be provided only above either the cathode region 181 or the anode region 182. For example, the oxide layer 66 may be provided above the cathode region 181, and the oxide layer 66 may not be provided above the anode region 182. On the contrary, the oxide layer 66 may be provided above the anode region 182, and the oxide layer 66 may not be provided above the cathode region 181. It may be determined whether the oxide layer 66 should be formed, in consideration of a resistance such that the temperature sensing unit 180 is not destabilized.

The cathode electrode 186 is electrically connected to the cathode region 181 via the contact hole 58. The cathode electrode 186 is one example of a front surface side metal layer 53. That is, the cathode electrode 186 may be formed of the same material as that of an emitter electrode 52. The cathode electrode 186 is electrically connected to a cathode pad 118 by a cathode wiring line 119.

The anode electrode 187 is electrically connected to the anode region 182 via the contact hole 58. The anode electrode 187 is one example of the front surface side metal layer 53. That is, the anode electrode 187 may be formed of the same material as that of the emitter electrode 52. The anode electrode 187 is electrically connected to an anode pad 116 by an anode wiring line 117.

An interlayer dielectric film 38 is provided on upper surfaces of the cathode region 181 and the anode region 182. The contact hole 58 may be formed in the interlayer dielectric film 38 of the temperature sensing unit 180.

Element regions such as a transistor portion 70 and a diode portion 80 may be provided below the temperature sensing unit 180. A collector region 22 is provided below the temperature sensing unit 180 in the present example. That is, the temperature sensing unit 180 in the present example is provided in the transistor portion 70. It should be noted that the temperature sensing unit 180 may be provided in the diode portion 80, or may be provided in a region away from an active portion 120 and in the vicinity of an edge termination structure portion 140. Therefore, a high concentration region like the collector region 22 may not be formed below the temperature sensing unit 180.

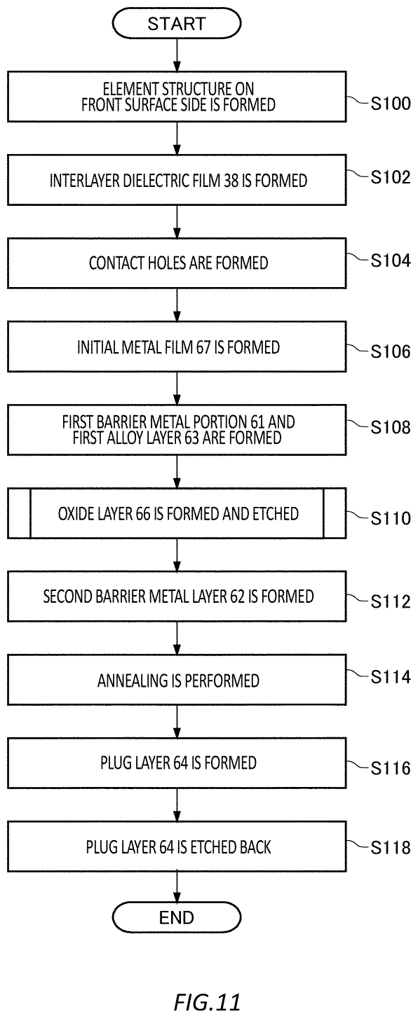

FIG. 11 is a flowchart showing one example of a process of manufacturing a semiconductor device 100. In a step S100, an element structure on a front surface 21 side of the semiconductor device 100 is formed. The step S100 may include a process of forming a dummy trench portion 30 and a gate trench portion 40 as the element structure on the front surface 21 side. The step S100 may include a process of forming, as the element structure on the front surface 21 side, a base region 14, an emitter region 12, a contact region 15, and the like by performing ion implantation with respect to a semiconductor substrate 10.

In a step S102, an interlayer dielectric film 38 is formed above the semiconductor substrate 10. The interlayer dielectric film 38 may be formed by stacking a plurality of dielectric films. In a step S104, contact holes are formed by etching the interlayer dielectric film 38. In the step S104, contact holes such as a contact hole 54, a contact hole 55, a contact hole 56, and a contact hole 58 may be formed in the interlayer dielectric film 38.

In a step S106, an initial metal film 67 for forming a first barrier metal portion 61 and a first alloy layer 63 is formed. In the present example, the initial metal film 67, which is predetermined, is formed on side walls of the interlayer dielectric film 38 and an upper surface of the semiconductor substrate 10 in the contact hole 54. That is, the initial metal film 67 is formed so as to be in contact with the interlayer dielectric film 38 and the semiconductor substrate 10. The initial metal film 67 may be composed of a first metal. A barrier metal layer 60, the first alloy layer 63, and an oxide layer 66 may be formed by processing the initial metal film 67. For example, the initial metal film 67 is a Ti film formed by sputtering. A film thickness of the initial metal film 67 may be 1 nm or more and 100 nm or less.

In a step S108, the semiconductor substrate 10 is annealed in a nitrogen atmosphere. As a result, the first barrier metal portion 61 is formed on the side walls of the interlayer dielectric film 38, and the first alloy layer 63 is formed on the upper surface of the semiconductor substrate 10. In this manner, the initial metal film 67 in contact with the interlayer dielectric film 38 becomes the first barrier metal portion 61, and the initial metal film 67 in contact with the semiconductor substrate 10 becomes the first alloy layer 63. The first barrier metal portion 61 in the present example is a dense TiN film formed by annealing the Ti film on the side walls of the interlayer dielectric film 38. The first alloy layer 63 in the present example is a titanium silicide film formed by annealing the Ti film on the upper surface of the semiconductor substrate 10. In the present example, a case will be described in which the TIN film is formed as the first barrier metal portion 61, but when a material of the first barrier metal portion 61 is not TiN, the initial metal film 67 made of a different material may be formed. An annealing temperature may be 300 degrees C. or more and 1100 degrees C. or less. Annealing for forming the first barrier metal portion 61 may be performed before a second barrier metal portion 62 is formed. It is to be noted that the initial metal film 67 may remain between the interlayer dielectric film 38 and the first barrier metal portion 61 without reacting.

In a step S110, the oxide layer 66 is formed and etched. In the step S110, the oxide layer 66 is formed after the first alloy layer 63 is formed on the upper surface of the semiconductor substrate 10. The oxide layer 66 may be formed before the second barrier metal portion 62 is formed. The oxide layer 66 is formed on an upper surface of the first alloy layer 63 in the contact hole 54. The oxide layer 66 may be formed on the entire exposed surface of the first alloy layer 63 in the contact hole 54. A step of forming the oxide layer 66 may include a step of wet etching, may include a step of dry etching, may include a step of annealing, or may include a step of depositing. Specific methods for forming and etching the oxide layer 66 will be specifically described later.

When the oxide layer 66 is formed by etching, in a process of forming the oxide layer 66, the first barrier metal portion 61 and/or the initial metal film 67 may be etched. As a result, the first barrier metal portion 61 and/or the initial metal film 67 may be adjusted to have a predetermined film thickness. The first barrier metal portion 61 may be etched to have a film thickness of 1 nm or more and 10 nm or less. The first barrier metal portion 61 and/or the initial metal film 67 may be completely removed by etching.

In a step S112, the second barrier metal portion 62 is formed above the first alloy layer 63. The second barrier metal portion 62 may be formed so as to be stacked on the first alloy layer 63 below the contact hole 54. When the oxide layer 66 remains on the first alloy layer 63, the second barrier metal portion 62 may be formed so as to be stacked on the oxide layer 66. The second barrier metal portion 62 may be formed so as to be stacked on the first barrier metal portion 61 and/or the initial metal film 67 on side walls of the contact hole 54. When the first barrier metal portion 61 and/or the initial metal film 67 are completely removed, the second barrier metal portion 62 may be formed in contact with the interlayer dielectric film 38 on the side walls of the contact hole 54. The second barrier metal portion 62 in the present example is a TiN film formed by sputtering.

In a step S114, the semiconductor substrate 10 is annealed in the nitrogen atmosphere. An annealing condition in the step S114 may be the same as or different from an annealing condition for forming the first barrier metal portion 61 and the first alloy layer 63 in the step S108. Annealing in the present example is performed after the second barrier metal portion 62 is formed. Annealing of the second barrier metal portion 62 may be performed before a plug layer 64 is formed.

In a step S116, the plug layer 64 is formed. In the present example, tungsten is formed so as to be filled inside the contact hole 54 by a chemical vapor deposition (CVD) method. When the oxide layer 66 on the upper surface of the first alloy layer 63 is not completely removed and is partially left, the oxide layer 66 on the upper surface of the first alloy layer 63 may function as a metal diffusion preventing layer during formation of the plug layer 64. Leaving the oxide layer 66 on the upper surface of the first alloy layer 63 can prevent the plug layer 64 from entering the first alloy layer 63 when the plug layer 64 is formed by CVD.

In a step S118, the plug layer 64 is etched back. Accordingly, an unnecessary tungsten film outside the contact hole 54 may be removed. Etching back may be performed by dry etching or chemical mechanical polishing (CMP). When the tungsten film is removed, the initial metal film 67, the first barrier metal portion 61, and the second barrier metal portion 62 on the interlayer dielectric film 38 may also be removed. The initial metal film 67, the first barrier metal portion 61, and the second barrier metal portion 62 on the interlayer dielectric film 38 may be removed in a process different from a process of etching back the plug layer 64. The initial metal film 67, the first barrier metal portion 61, and the second barrier metal portion 62 on the interlayer dielectric film 38 may not be removed. Etching back of the barrier metal layer 60 and the plug layer 64 may be omitted.

After the step S118, a front surface side metal layer 53 may be formed above the semiconductor substrate 10. In addition, after the step S118, a member on a back surface 23 side such as a collector electrode 24 may be formed. After the step S118, a back surface side lifetime control region 151 and a front surface side lifetime control region 152 may be formed.

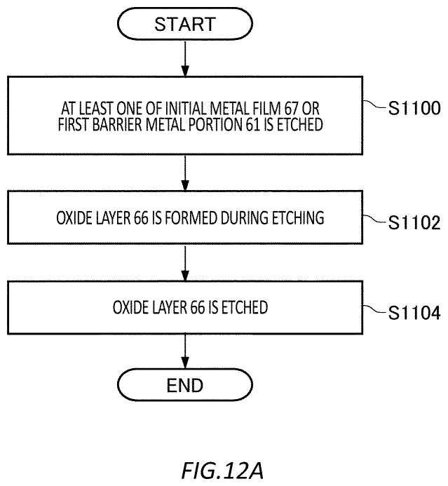

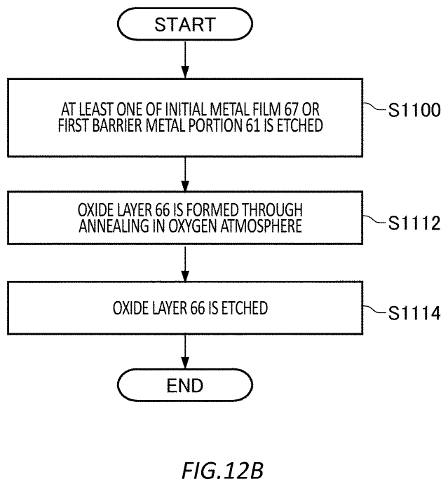

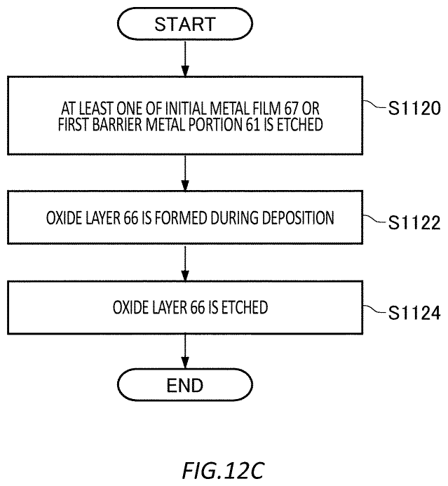

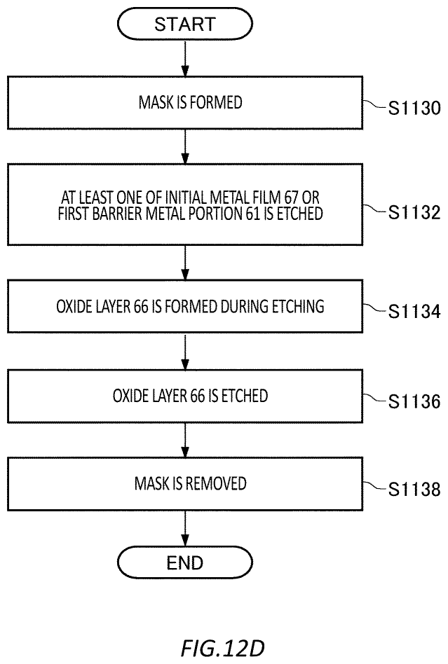

FIG. 12A shows one example of a process of forming an oxide layer 66. In the present example, a method for forming the oxide layer 66 by etching will be described. Steps S1100 to S1104 are examples of the step S110 in FIG. 11.

In the step S1100, at least one of an initial metal film 67 or a first barrier metal portion 61 is etched. The initial metal film 67 on an upper surface of a first alloy layer 63 may be etched, and the first barrier metal portion 61 formed on side walls of an interlayer dielectric film 38 may be etched. When the initial metal film 67 has remained on a surface of the first barrier metal portion 61 on a side opposite to the interlayer dielectric film 38, the initial metal film 67 on the first barrier metal portion 61 may be removed by etching. The initial metal film 67 which has remained may be etched after a step of forming the first alloy layer 63 and before a step of forming a second barrier metal portion 62.

In the present example, at least one of the initial metal film 67 or the first barrier metal portion 61 is wet etched, but it may be dry etched. A step of wet etching at least one of the initial metal film 67 or the first barrier metal portion 61 may include a step of wet etching it using hydrogen peroxide. A chemical liquid for wet etching may be hydrogen peroxide, may be buffered hydrofluoric acid, or may be another chemical liquid such as hydrofluoric acid or ammonium hydroxide.

In the step S1102, the oxide layer 66 may be formed during etching. In a contact hole 54, the oxide layer 66 may be formed on the upper surface of the first alloy layer 63. The oxide layer 66 may be formed by oxidizing the upper surface of the first alloy layer 63 by wet etching.

In the step S1104, the oxide layer 66 which has been formed may be etched. A step of etching the oxide layer 66 may include a step of wet etching the oxide layer 66. A chemical liquid for wet etching may be hydrogen peroxide, may be buffered hydrofluoric acid, or may be another chemical liquid such as hydrofluoric acid or ammonium hydroxide. The step of etching the oxide layer 66 may include a step of dry etching the oxide layer 66. The step of etching the oxide layer 66 may include a step of physically etching the oxide layer 66 by sputtering or the like.

In the step of etching the oxide layer 66, the oxide layer 66 may be etched until the upper surface of the first alloy layer 63 is exposed. In addition, in the step of etching the oxide layer 66, the oxide layer 66 may be thinned, and etched such that the oxide layer 66 remains on the upper surface of the first alloy layer 63. A resistance in the contact hole 54 can be changed by adjusting a film thickness of the oxide layer 66.

Each of etching processes in the steps S1100 to S1104 may be performed in the same etching process. The initial metal film 67 and the oxide layer 66 may be etched in the same etching process, and the first barrier metal portion 61 and the oxide layer 66 may be etched in the same etching process. In the same etching process, formation of the oxide layer 66 and etching of the oxide layer 66 may be repeated on the upper surface of the first alloy layer 63.

FIG. 12B shows one example of a process of forming an oxide layer 66. In the present example, a method for forming the oxide layer 66 by annealing will be described. Steps S1110 to S1114 are examples of the step S110 in FIG. 11. The present example is different from the embodiment example in FIG. 12A in that the step S1112 is a step of annealing. In the present example, difference with FIG. 12A will be particularly described.

In the step S1112, the oxide layer 66 is formed by annealing a semiconductor substrate 10 in an oxygen atmosphere. As a result, the oxide layer 66 is formed on an upper surface of a first alloy layer 63. Selectively forming a mask on the upper surface of the first alloy layer 63 may form the oxide layer 66 in a region where the mask has not been formed, and may not form the oxide layer 66 in a region where the mask has been formed.

FIG. 12C shows one example of a process of forming an oxide layer 66. In the present example, a method for forming the oxide layer 66 by depositing will be described. Steps S1120 to S1124 are examples of the step S110 in FIG. 11. The present example is different from the embodiment example in FIG. 12A in that the step S1122 is a step of depositing. In the present example, difference with FIG. 12A will be particularly described.

In the step S1122, the oxide layer 66 is deposited on a semiconductor substrate 10 by a CVD method, a sputtering method, or the like. The oxide layer 66 may be, for example, a low temperature oxide (LTO) film or a HTO film. As a result, the oxide layer 66 is formed on an upper surface of a first alloy layer 63. Selectively forming a mask on the upper surface of the first alloy layer 63 may form the oxide layer 66 in a region where the mask has not been formed, and may not form the oxide layer 66 in a region where the mask has been formed.

FIG. 12D shows one example of a process of forming an oxide layer 66. In the present example, a case will be described in which a mask is used to selectively form the oxide layer 66. Steps S1130 to S1138 are examples of the step S110 in FIG. 11.

In the step S1130, the mask is formed above a semiconductor substrate 10. For example, the mask is formed in a region to be protected from etching. The mask may be formed in one of a first conductivity type region 161 or a second conductivity type region 162, and the mask may not be formed in another of them. The mask may be formed above a contact region 15, and the mask may not be formed above an emitter region 12. When the oxide layer 66 is not formed above a polycrystalline layer 165, the mask may be formed in a contact hole 58 above the polycrystalline layer 165.

In the step S1132, at least one of an initial metal film 67 or a first barrier metal portion 61 is etched. In the step S1132, at least one of the initial metal film 67 or the first barrier metal portion 61 may be etched with the same method as in FIG. 12A, FIG. 12B, or FIG. 12C.

In the step S1134, the oxide layer 66 may be formed during etching in the step S1132. In the present example, since the mask is formed above the semiconductor substrate 10, the oxide layer 66 can be selectively formed. The oxide layer 66 may be formed on a part of an upper surface of a first alloy layer 63, and the oxide layer 66 may not be formed on another part. The oxide layer 66 may be formed in one of the first conductivity type region 161 or the second conductivity type region 162, and the oxide layer 66 may not be formed in another of them. The oxide layer 66 may be formed above the emitter region 12, and the oxide layer 66 may not be formed above the contact region 15. The oxide layer 66 may not be formed in the contact hole 58 above the polycrystalline layer 165.

In the step S1136, the oxide layer 66 may be etched. The mask formed in the step S1130 may be used to selectively etch a region where the oxide layer 66 has been formed. The oxide layer 66 may be selectively etched by forming the mask after forming the oxide layer 66. As a result, the oxide layers 66 having different film thicknesses can be formed.

In the step S1138, the mask provided above the semiconductor substrate 10 is removed. Subsequently, the process may proceed to the step S112 in FIG. 11, and a second barrier metal portion 62 may be formed.

In this manner, the oxide layer 66 may be selectively provided using the mask provided above the semiconductor substrate 10. The oxide layer 66 may be selectively etched using the mask after the oxide layer 66 is formed. In addition, the oxide layer 66 may be selectively formed using the mask. That is, performing the steps S1130 to S1138 and then further performing the steps S1130 to S1138 may form the oxide layer 66 in a region different from a region where the steps were firstly performed, to etch the oxide layer 66 which has been formed.

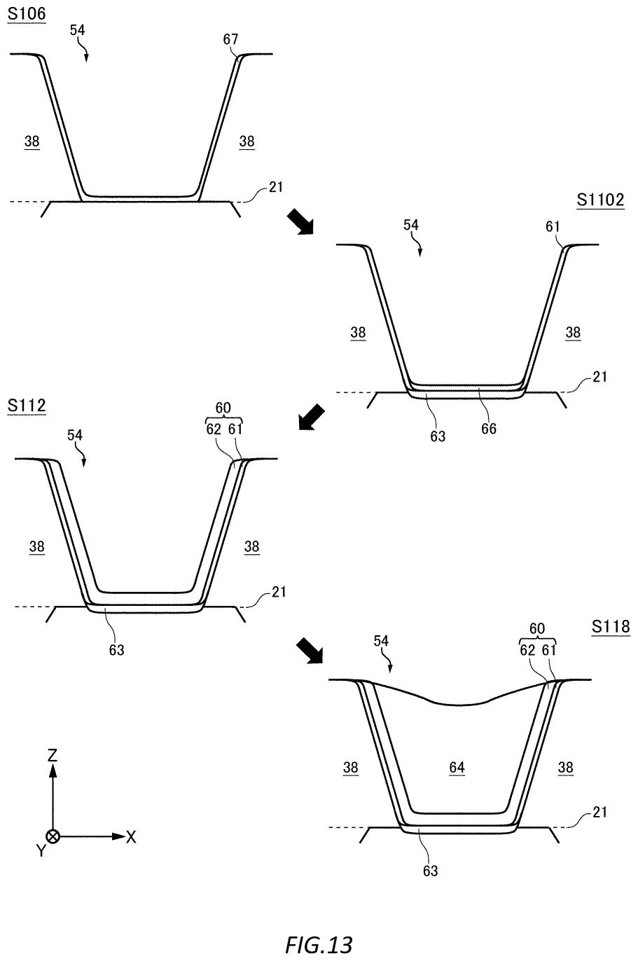

FIG. 13 shows one example of a method for manufacturing a semiconductor device 100. The present example shows a cross section in the vicinity of a contact hole 54 according to the flowchart of the manufacturing method shown in FIG. 12A.

In the step S106, an initial metal film 67 is formed on side walls of an interlayer dielectric film 38 and an upper surface of the semiconductor substrate 10. The initial metal film 67 in the present example is formed on an upper surface of a front surface 21. The initial metal film 67 may be formed also on the upper surface of the interlayer dielectric film 38.

In the step S1102, an oxide layer 66 is formed on the upper surface of a first alloy layer 63. The initial metal film 67 formed in the step S106 has changed into a first barrier metal portion 61 or the first alloy layer 63 by annealing in a nitrogen atmosphere. It should be noted that at least part of the initial metal film 67 may remain without reacting.

In the step S112, a second barrier metal portion 62 is formed inside the contact hole 54. In the step S118, a plug layer 64 is formed farther inward than the second barrier metal portion 62.

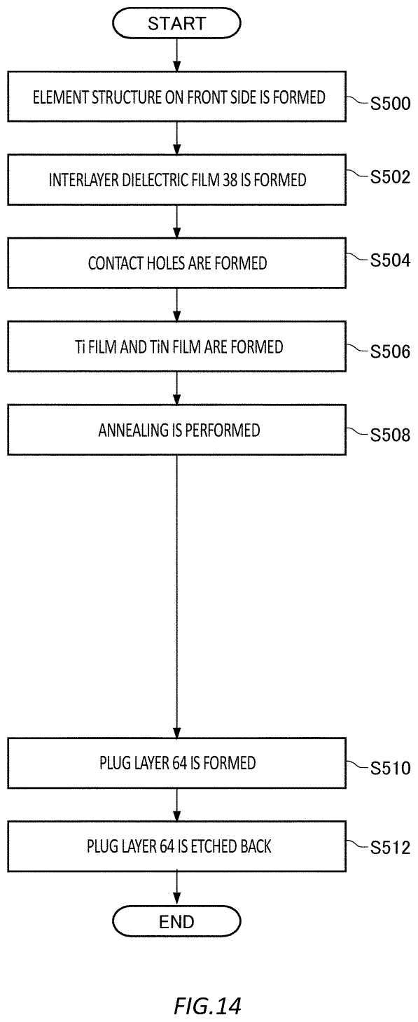

FIG. 14 is a flowchart showing a process of manufacturing a semiconductor device according to a comparative example. Steps S500 to S504 may be respectively the same as the steps S100 to S104 in FIG. 11.

In a step S506, a Ti film and a TiN film are formed inside a contact hole. In a step S508, a semiconductor substrate 10 is annealed in a nitrogen atmosphere, to form a dense TIN film from the Ti film on side walls of an interlayer dielectric film 38. A titanium silicide layer is formed at an upper surface of the semiconductor substrate 10.

In a step S510, a plug layer 64 is formed inside the contact hole. In a step S512, the plug layer 64 is etched back.

In this manner, in the semiconductor device according to the comparative example, the Ti film and the TiN film are formed together, and an oxide layer 66 may not be formed on an upper surface of a first alloy layer 63. Therefore, there is no process of etching the oxide layer 66. In addition, part of the Ti film may not be nitrided, and Ti having a hydrogen absorbing effect may remain.

In contrast, in a semiconductor device 100, etching the oxide layer 66 formed on the upper surface of the first alloy layer 63 can remove an unreacted first metal having a hydrogen absorbing effect, and reduce a resistance in the contact hole while terminating a defect around a MOS gate structure with hydrogen and suppressing a variation in a threshold voltage. In addition, in the semiconductor device 100, separating a region where the oxide layer 66 is left and a region where it is removed can select an appropriate structure depending on the contact hole and improve characteristics of the semiconductor device 100.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that embodiments added with such alterations or improvements can be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 20: buffer region, 21: front surface, 22: collector region, 23: back surface, 24: collector electrode, 25: connection portion, 26: dielectric film, 30: dummy trench portion, 31: extending portion, 32: dummy dielectric film, 33: connecting portion, 34: dummy conductive portion, 38: interlayer dielectric film, 40: gate trench portion, 41: extending portion, 42: gate dielectric film, 43: connecting portion, 44: gate conductive portion, 50: gate metal layer, 52: emitter electrode, 53: front surface side metal layer, 54: contact hole, 55: contact hole, 56: contact hole, 58: contact hole, 60: barrier metal layer, 61: first barrier metal portion, 62: second barrier metal portion, 63: first alloy layer, 64: plug layer, 65: trench contact portion, 66: oxide layer, 67: initial metal film, 68: covering layer, 70: transistor portion, 71: mesa portion, 80: diode portion, 81: mesa portion, 82: cathode region, 85: extension region, 90: boundary portion, 91: mesa portion, 100: semiconductor device, 102: end side, 112: gate pad, 114: sensing electrode, 115: current sensing unit, 116: anode pad, 117: anode wiring line, 118: cathode pad, 119: cathode wiring line, 120: active portion, 130: outer circumferential gate runner, 131: gate runner between active portions, 140: edge termination structure portion, 151: back surface side lifetime control region, 152: front surface side lifetime control region, 161: first conductivity type region, 162: second conductivity type region, 165: polycrystalline layer, 180: temperature sensing unit, 181: cathode region, 182: anode region, 184: interlayer dielectric film, 186: cathode electrode, 187: anode electrode.

What is claimed is:

1. A method for manufacturing a semiconductor device, the method comprising:
forming an interlayer dielectric film having a contact hole above a semiconductor substrate;
forming an initial metal film containing a predetermined first metal on an upper surface of the semiconductor substrate and on side walls of the interlayer dielectric film in the contact hole;
forming a first alloy layer containing the first metal on the upper surface of the semiconductor substrate;
forming a first barrier metal portion containing the first metal on the side walls of the interlayer dielectric film;
etching at least one of the initial metal film or the first barrier metal portion in the contact hole;
forming an oxide layer on an upper surface of the first alloy layer in the contact hole;
etching the oxide layer in the contact hole;
forming a second barrier metal portion, which is conductive, above the first alloy layer in the contact hole; and
forming a plug layer above the second barrier metal portion in the contact hole.

2. The method for manufacturing a semiconductor device according to claim 1, wherein
the forming the first alloy layer includes annealing the initial metal film provided on the upper surface of the semiconductor substrate.

3. The method for manufacturing a semiconductor device according to claim 1, wherein
the forming the first barrier metal portion includes annealing the initial metal film provided on the side walls of the interlayer dielectric film.

4. The method for manufacturing a semiconductor device according to claim 1, wherein
the forming the oxide layer includes annealing the semiconductor substrate in an oxygen atmosphere.

5. The method for manufacturing a semiconductor device according to claim 1, the method comprising
etching the initial metal film, which has remained, in the contact hole after the forming the first alloy layer and before the forming the second barrier metal portion.

6. The method for manufacturing a semiconductor device according to claim 5, wherein
the initial metal film and the oxide layer are etched in a same etching process.

7. The method for manufacturing a semiconductor device according to claim 1, wherein
the etching the oxide layer includes wet etching the oxide layer.

8. The method for manufacturing a semiconductor device according to claim 7, wherein
a chemical liquid for the wet etching is hydrogen peroxide or buffered hydrofluoric acid.

9. The method for manufacturing a semiconductor device according to claim 1, wherein
the etching the oxide layer includes dry etching the oxide layer.

10. The method for manufacturing a semiconductor device according to claim 1, wherein
in the etching the oxide layer, the oxide layer is etched until the upper surface of the first alloy layer is exposed.

11. The method for manufacturing a semiconductor device according to claim 1, wherein
in the etching the oxide layer, the oxide layer is thinned, and etched such that the oxide layer remains on the upper surface of the first alloy layer.

12. The method for manufacturing a semiconductor device according to claim 1, wherein
the oxide layer is selectively provided using a mask provided above the semiconductor substrate.

13. The method for manufacturing a semiconductor device according to claim 1, the method comprising:
forming, at a front surface of the semiconductor substrate, a first conductivity type region of a first conductivity type having a higher doping concentration than a drift region provided in the semiconductor substrate; and
forming a second conductivity type region of a second conductivity type at the front surface of the semiconductor substrate, wherein
a film thickness of the oxide layer is greater above the first conductivity type region than above the second conductivity type region.

14. The method for manufacturing a semiconductor device according to claim 13, wherein
the oxide layer is not provided above the second conductivity type region.

15. The method for manufacturing a semiconductor device according to claim 13, wherein
the first conductivity type region is an emitter region of the first conductivity type provided above the drift region in a transistor portion provided in the semiconductor substrate, and
the second conductivity type region is a contact region of the second conductivity type having a higher doping concentration than a base region of the second conductivity type provided above the drift region in the transistor portion provided in the semiconductor substrate.

16. The method for manufacturing a semiconductor device according to claim 1, the method comprising:
forming a polycrystalline layer above the semiconductor substrate or in the semiconductor substrate;
forming an oxide layer on an upper surface of the polycrystalline layer in a contact hole above the polycrystalline layer; and
etching the oxide layer on the upper surface of the polycrystalline layer.

17. The method for manufacturing a semiconductor device according to claim 16, wherein
the polycrystalline layer is a gate runner electrically connected to a gate pad.

18. The method for manufacturing a semiconductor device according to claim 1, the method comprising
forming a trench contact portion which has the contact hole and extends from a front surface of the semiconductor substrate in a depth direction of the semiconductor substrate.

19. The method for manufacturing a semiconductor device according to claim 1, the method comprising
forming a front surface side lifetime control region on a front surface side with respect to a center of the semiconductor substrate in a depth direction of the semiconductor substrate.

20. The method for manufacturing a semiconductor device according to claim 19, wherein
the front surface side lifetime control region is formed by irradiating the semiconductor substrate with a particle beam.

21. A method for manufacturing a semiconductor device, the method comprising:
forming an interlayer dielectric film having a contact hole above a semiconductor substrate;
forming an initial metal film containing a predetermined first metal on an upper surface of the semiconductor substrate and on side walls of the interlayer dielectric film in the contact hole;
forming a first alloy layer containing the first metal on the upper surface of the semiconductor substrate;
etching the initial metal film in the contact hole;
forming an oxide layer on an upper surface of the first alloy layer in the contact hole;
etching the oxide layer in the contact hole;
forming a second barrier metal portion, which is conductive, above the first alloy layer in the contact hole; and
forming a plug layer above the second barrier metal portion in the contact hole.
